(19) United States
(12) Patent Application Publication
(10) Pub. No.: US 2026/0236624 A1
(43) Pub. Date: Aug. 13, 2026

(54) METHODS FOR DESIGNING ELECTROMAGNETIC STRUCTURES, AND COMPONENTS, APPARATUSES, AND SYSTEMS EMPLOYING THE SAME

(71) Applicant: HUAWEI TECHNOLOGIES CO., LTD., Shenzhen (CN)

(72) Inventors: Chandan Roy, Ottawa (CA); Ming Jian, Ottawa (CA); Peyman Neshaastegaran, Ottawa (CA); Wenyao Zhai, Ottawa (CA)

(21) Appl. No.: 19/051,890

(22) Filed: Feb. 12, 2025

(51) Int. Cl. G06F 30/10; G06F 30/27

(52) U.S. Cl. CPC G06F 30/10; G06F 30/27

(57) ABSTRACT

A method is described which comprises determining a shape of a planar electromagnetic structure for optimizing one or more performance measures of the planar electromagnetic structure, the shape of the planar electromagnetic structure being defined by a plurality of vertices. Said determining the shape of the planar electromagnetic structure comprises determining locations of the plurality of vertices, a location of each vertex of the plurality of vertices being selected from a plurality of candidates variable within a corresponding geometric shape from a plurality of geometric shapes, and at least one of the plurality of geometric shapes is a two-dimensional geometric shape and the location of at least one vertex of the plurality of vertices is selected from a plurality of candidates variable with respect to two dimensions independently within the two-dimensional geometric shape.

### FIELD OF THE DISCLOSURE

The present disclosure relates generally to electromagnetic structures, and in particular to methods for designing electromagnetic structures using artificial intelligence, and components, apparatuses, and systems employing electromagnetic structures designed and fabricated using same.

### BACKGROUND

Electromagnetic structure design plays a crucial role in the development of modern wireless communication systems, particularly in the field of antenna design. The rapid evolution of wireless communication systems, including 5G, Internet of Things (IoT), satellite communication, and the future generation of wireless communication networks (e.g., 6G networks), demands advanced antenna solutions capable of operations in a variety of applications such as multiband and wideband applications. However, it remains a challenge for designing electromagnetic structures that balance between bandwidth enhancement, size, efficiency, and/or ease of integration.

Some evolutionary algorithms and surrogate modeling approaches for designing electromagnetic structures suffer from various constraints such as non-convexity of the design space, computational intensity of electromagnetic simulations, and/or limitations of predefined templates.

Therefore, there is a desire of a method for designing and optimizing shapes of various electromagnetic structures that address at least some of the limitations of these methods.

### SUMMARY

According to one aspect of this disclosure, there is provided a method comprising determining a shape of a planar electromagnetic structure for optimizing one or more performance measures of the planar electromagnetic structure, the shape of the planar electromagnetic structure being defined by a plurality of vertices; wherein said determining the shape of the planar electromagnetic structure comprises determining locations of the plurality of vertices, a location of each vertex of the plurality of vertices being selected from a plurality of candidates variable within a corresponding geometric shape from a plurality of geometric shapes, and at least one of the plurality of geometric shapes is a two-dimensional geometric shape and the location of at least one vertex of the plurality of vertices is selected from a plurality of candidates variable with respect to two dimensions independently within the two-dimensional geometric shape.

In some implementations, the plurality of geometric shapes comprises one or more of a straight line, a rectangular shape, or a triangular shape.

In some implementations, each of the plurality of geometric shapes comprises boundaries determined based on a target frequency range of the planar electromagnetic structure.

In some implementations, each of the plurality of candidates represents coordinates within the boundaries of the corresponding geometric shape.

In some implementations, each vertex of the plurality of vertices is represented as a coordinate pair in a Cartesian coordinate system.

In some implementations, said determining the shape of the electromagnetic structure further comprises determining a location of a feed point of the planar electromagnetic structure.

In some implementations, the method further comprises fabricating the planar electromagnetic structure having the shape defined by the plurality of vertices at the determined locations thereof.

In some implementations, the planar electromagnetic structure is at least a portion of a transmitter or a receiver.

In some implementations, the determining the locations of the plurality of vertices of the shape of the planar electromagnetic structure is performed using an artificial intelligence (AI) model.

In some implementations, the AI model comprises a convolutional neural network (CNN) model.

In some implementations, the AI model receives a value of a frequency as a parameter for optimizing the one or more performance measures of the electromagnetic structure.

In some implementations, the one or more performance measures of the planar electromagnetic structure comprises one or more scattering parameters of the planar electromagnetic structure.

In some implementations, the one or more performance measures of the planar electromagnetic structure comprises a return loss parameter S₁₁ of the planar electromagnetic structure.

In some implementations, the determining the locations of the plurality of vertices of the shape of the planar electromagnetic structure is performed using the AI and a genetic algorithm.

In some implementations, said determining the shape of the planar electromagnetic structure further comprises simulating the planar electromagnetic structure having the shape defined by the plurality of vertices; and comparing results of said simulation with the one or more performance measures for optimization verification.

In some implementations, the method further comprises selecting the locations of the plurality of vertices; and simulating the planar electromagnetic structure having the shape defined by the plurality of vertices at the locations selected by the computational software; and collecting the selected locations and results of said simulation as data for training the AI model.

In some implementations, the method further comprises selecting the locations of the plurality of vertices is performed by a computational software; and said simulating the planar electromagnetic structure is performed by a full-wave electromagnetic simulation software.

In some implementations, the method further comprises repeating said determining the shape of the planar electromagnetic structure for a plurality of times to obtain a plurality of shapes of the electromagnetic structure; and selecting one of the plurality of shapes of the planar electromagnetic structure based on one or more requirements of a use case.

According to one aspect of this disclosure, there is provided one or more apparatuses comprising: one or more non-transitory computer-readable storage media or medium; and one or more processors functionally coupled to the one or more non-transitory computer-readable storage media or medium; the one or more non-transitory computer-readable storage media or medium comprising computer-executable instructions; and the instructions, when executed, cause one or more circuits to perform the above-described method.

According to one aspect of this disclosure, there is provided one or more non-transitory computer-readable storage media or medium comprising computer-executable instructions, wherein the instructions, when executed, cause one or more circuits such as one or more processors to perform the above-described method.

The various implementations disclosed herein provide a method of electromagnetic structure design and/or fabrication suitable for manipulating fundamental and higher order modes for a variety of applications such as multiband and wideband applications. The examples demonstrated also show that the electromagnetic structure designed according to the implementations can be optimized for different performance parameters such as circular polarization characteristics.

### BRIEF DESCRIPTION OF THE DRAWINGS

For a more complete understanding of the disclosure, reference is made to the following description and accompanying drawings, in which:

FIG. 1 is a schematic diagram showing the optimization of a shape of an electromagnetic structure comprising a plurality of vertices, according to some implementations of this disclosure;

FIG. 2 is a schematic diagram showing the geometric shapes of the vertices as shown in FIG. 1 and their respective boundaries, for optimization of the shape of an electromagnetic structure;

FIG. 3 is a schematic diagram showing a plurality of candidates for each vertex as shown in FIG. 1, within their respective boundaries of the geometric shapes;

FIGS. 4A, 4B, and 4C are schematic diagrams showing some examples of shapes of electromagnetic structures that can be optimized using the described method according to some implementations of this disclosure;

FIG. 5 is a schematic diagram showing the structure of a convolutional neural network (CNN) model used by the described method for optimizing the shape of an electromagnetic structure, according to some implementations of this disclosure;

FIGS. 6A and 6B are flowcharts illustrating the workflow for designing an electromagnetic structure using the described method, according to some implementations of this disclosure;

FIG. 7 is a flowchart showing the details of step 618, according to some implementations of this disclosure;

FIG. 8 is a schematic diagram showing an example of optimizing a shape of an electromagnetic structure comprising a plurality of vertices;

FIG. 9 is a schematic diagram showing the geometric shapes of the vertices shown in FIG. 8 and their respective boundaries, according to some implementations of this disclosure;

FIG. 10 is a schematic diagram showing a plurality of candidates for each vertex as shown in FIG. 9, within their respective boundaries of the geometric shapes;

FIG. 11A is a schematic diagram showing an example of a patch antenna whose electromagnetic shape is to be optimized, the patch antenna comprising a plurality of vertices A-M;

FIG. 11B is a schematic diagram showing an example of the dimensions of the patch antenna shown in FIG. 11A;

FIG. 12 is a schematic diagram showing inputs and outputs of an AI model, according to some implementations of this disclosure;

FIG. 13 is a schematic diagram showing the structure of a CNN model used by the described method for optimizing the shape of the patch antenna shown in FIG. 11A, according to some implementations of this disclosure;

FIG. 14 is a plot showing the epoch vs the mean square error (MSE) of the developed model of the patch antenna for training and validation;

FIG. 15A is a plot showing a first example of an optimized dual-band patch antenna, according to some implementations of this disclosure;

FIG. 15B is a plot showing a second example of an optimized dual-band patch antenna, according to some implementations of this disclosure;

FIG. 15C is a plot showing a third example of an optimized wideband patch antenna, according to some implementations of this disclosure;

FIG. 15D is a plot showing a fourth example of an optimized wideband patch antenna, according to some implementations of this disclosure;

FIGS. 16A to 16D are plots showing the S₁₁ parameters of the designed antennas shown in FIGS. 15A to 15D, respectively;

FIG. 17A is a plot showing the far-field radiation patterns at the center frequency of a first band of the optimized dual-band patch antenna shown in FIG. 15A;

FIG. 17B is a plot showing the far-field radiation patterns at the center frequency of a second band of the optimized dual-band patch antenna shown in FIG. 15A;

FIG. 17C is a plot showing the far-field radiation patterns at the center frequency of a first band of the optimized dual-band patch antenna shown in FIG. 15B;

FIG. 17D is a plot showing the far-field radiation patterns at the center frequency of a second band of the optimized dual-band patch antenna shown in FIG. 15B;

FIG. 17E and FIG. 17F are plots showing the axial ratio (AR) of the optimized wideband antennas shown in FIG. 15C and FIG. 15D, respectively.

FIG. 18 is a schematic diagram showing a simplified hardware structure of a computing device for designing and/or fabricating an electromagnetic structure using the method, according to some implementations of this disclosure; and

FIG. 19 is a schematic diagram showing a simplified software architecture of the computing device shown in FIG. 18.

### DETAILED DESCRIPTION

At least some implementations herein are related to methods for designing planar electromagnetic structures using artificial intelligence (AI) such as deep learning, and components, apparatuses, and systems employing electromagnetic structures designed and fabricated using same.

Electromagnetic (EM) structures are conductors and/or electromagnetically conductive components (such as filters, resonators and radiating elements (for example, antennas)) used in circuits for their designed purposes such as signal filtering, signal resonating, signal transmission, signal receiving, and/or the like. The electromagnetic structures may be, for example, in the form of etched conductive strips of specific shapes on a printed circuit board (PCB). In some implementations, the term “shape” refers to the electromagnetic shape of an electromagnetic structure. In some implementations, the electromagnetic structure may be at least a portion of a transmitter or a receiver.

The rapid evolution of wireless communication systems, including 5G, Internet of Things (IoT), satellite communication, and the future generation of wireless communication networks (e.g., 6G networks), demands advanced antenna solutions capable of operations in a variety of applications such as multiband and wideband applications.

Multiband EM structures (e.g., antennas) can enable seamless functionality across multiple frequency ranges, reducing device complexity and saving space. Wideband EM structures, on the other hand, can ensure continuous coverage for spectrum sensing, ultra-wideband (UWB) communication, and broadband radar. However, it remains a challenge for designing electromagnetic structures that balance between bandwidth enhancement, size, efficiency, and/or ease of integration.

Circularly polarized (CP) EM structures can also be desirable in modern communication systems due to their ability to mitigate polarization mismatch, enhance signal reliability, and/or resist multipath fading, making them ideal for applications such as satellite communication, Global Positioning System (GPS), and IoT. By transmitting and receiving signals with a rotating electric field, CP EM structures can perform effectively even in dynamic or unpredictable environments. However, designing CP antennas can also be challenging, as it may require precise amplitude and phase balance between orthogonal field components, along with achieving high axial ratio (AR) bandwidth, broad impedance matching, and/or compact size, all of which may call for innovative design methodologies.

Some antenna design methods, often relying on evolutionary algorithms such as genetic algorithms and particle swarm optimization, are limited by the non-convexity of the design space and the computational intensity of electromagnetic simulations. These constraints restrict the degrees of freedom and limit the exploration of the design space. To overcome these limitations, data-driven surrogate modeling has emerged as a promising approach. However, many methods rely on predefined templates for antenna structures, which inherently constrain the design space and may hinder the discovery of truly optimal solutions. Addressing these challenges may require design methodologies that expand the design space and optimize performance to meet the demands of modern wireless communication systems.

Slot-loaded planar EM structures can be used to achieve multiband, wideband, and CP operation, making them highly suitable for modern communication systems. By introducing strategically placed slots into the planar radiating element, designers can tailor the current distribution, enabling multiple resonances for multiband operation or broad impedance bandwidth for wideband applications. The shape, size, and/or orientation of the slots can directly influence the EM structures' performance, allowing precise tuning of frequency bands and polarization characteristics. For CP operation, asymmetrical or crossed slot configurations can often be employed to generate orthogonal field components with the required amplitude and phase balance. This flexibility, combined with their low profile and ease of fabrication, makes slot-loaded planar EM structure a good choice for compact and high-performance antenna designs.

Vector graphics can be utilized to define patch EM structure geometries, offering greater flexibility and generalization compared to some traditional geometric shapes. By representing the patch structure as a vector graphic, the design space can be expanded, allowing for the inclusion of more optimization variables. This is achieved by directly manipulating the vertices of the patch structure, enabling intricate shape customization to meet specific performance requirements such as multiband, wideband, or circular polarization characteristics.

However, some methods may have various limitations that can likely restrict the designs of the EM structures, such as:

### Ad Hoc Nature of the Slot Placement:

Some design processes typically begin with arbitrarily placing a slot of unspecified shape and location within a target patch structure, lacking generality and adaptability, as the arbitrary nature of the initial choices limits its applicability for systematic optimization across diverse performance requirements.

### Degree of Freedom in the Structure:

Some design methods involve one-dimensional variables which may restrict the degree of freedom in the structure and unable to incorporate design features such as slots or cuts, which are desirable for achieving wide impedance bandwidth and circular polarization performance.

### Limited Optimization Variables in Some Techniques:

Many methods also suffer from a limited number of optimization variables, which restrict their ability to fully leverage advanced machine learning techniques. A robust methodology is therefore desirable to maximize the number of optimization variables while carefully managing their boundaries to ensure efficient and effective optimization to fully utilize the potential of modern computational techniques for exploring complex design spaces.

Various implementations of this disclosure provide methods of designing electromagnetic structures, methods of designing planar electromagnetic structures that can accommodate slots and/or slits and that can increase the degree of freedom, suitable for a variety of applications such as multiband and wideband, and/or circularly polarized applications.

According to the methods described in various implementations, the shape of a planar electromagnetic structure can be represented by a plurality of vertices on a two-dimensional (2D) plane. The location/position of each vertex of the plurality of vertices can be selected from a plurality of candidates (may also be referred to as “samples”) variable within a corresponding geometric shape from a plurality of geometric shapes. As will be explained in more detail, in some implementations, at least one of the plurality of geometric shapes is a two-dimensional geometric shape and the location of at least one vertex of the plurality of vertices is selected from a plurality of candidates variable with respect to two dimensions independently (i.e., with respect to two perpendicular axes independently in a coordinate system) within the two-dimensional geometric shape. Hereinafter, the terms “vary two-dimensionally” or “two-dimensional variation” refers to variation with respect to two dimensions independently; the terms “vary one-dimensionally” or “one-dimensional variation” refers to variation with respect to one dimension, which can be with respect to one of the two perpendicular axes in a coordinate system or along a straight line.

This approach not only enhances the adaptability of the design but also opens up opportunities for discovering configurations that improve the performance of the EM structure. The increased degrees of freedom in the optimization process enable the generation of designs that would be difficult or impossible to achieve using fixed-template methods. This method addresses the growing demands of modern communication systems for compact, high-performance, and multifunctional antennas.

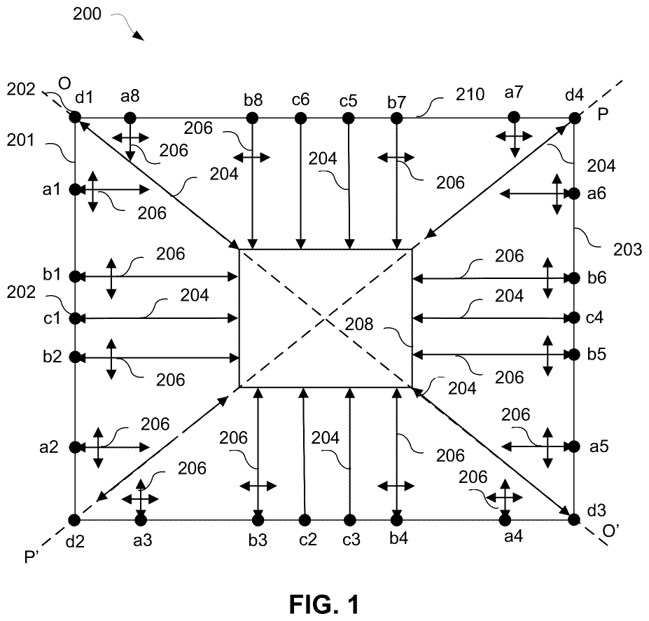

FIG. 1 is a schematic diagram showing the formation of a shape of a planar electromagnetic structure using a plurality of vertices, according to some implementations of this disclosure. In some implementations, the design process can begin with a predefined or preconfigured shape, such as a polygon. In one exemplary example, the design process may begin with a rectangular design space 201, also referred to as the primary patch.

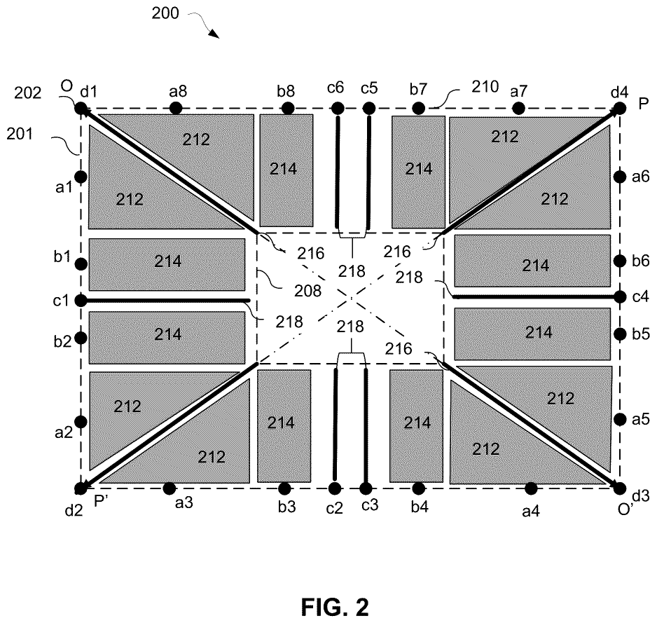

Referring to FIGS. 1 and 2, points 202 can be strategically placed along the edges of the predefined or preconfigured design space 201. These points, connected sequentially by straight lines, form a polygon representing the complete patch (also identified using reference numeral 200), with each point serving as a vertex. Location/position of one or more vertices 202 may be movable (as indicated by arrows 204, 206) within a corresponding geometric shape of a plurality of geometric shapes 212, 214, 216, 218. Arrows 204 are used to denote a one-dimensional (1D) variation. Such one-dimensional variation can be along one of the two perpendicular axes of a coordinate system (such as a Cartesian coordinate system), or along a straight line (where the variations to the pair of coordinates are correlated). Arrows 206 are used to denote a two-dimensional (2D) variation (i.e., with respect to the two perpendicular axes of a coordinate system independently). Here the vertices 202 shown in FIGS. 1 and 2 are all designated as variables (i.e., movable or variable within a corresponding geometric shape of a plurality of geometric shapes 212, 214, 216, 218). It will become apparent in some implementations that one or more of the vertices 202 may be fixed at their respective designated locations, and these fixed vertices will not be movable or variable within a corresponding geometric shape.

The plurality of geometric shapes 212, 214, 216, 218 comprise one or more of a one-dimensional geometric shape 216, 218 (e.g., straight lines), or a two-dimensional geometric shape 212, 214. In some implementations, at least one of the plurality of geometric shapes is a two-dimensional geometric shape, such as a triangular shape 212, or a rectangular shape 214, as shown in FIG. 2.

When a vertex 202 is movable or variable along a one-dimensional direction 204 within a one-dimensional geometric shape 216, 218, the corresponding vertex 202 can be referred to as a 1D variable; and when a vertex is movable or variable along a two-dimensional direction 206 within a two-dimensional geometric shape 212, 214, the corresponding vertex 202 can be referred to as a 2D variable.

In some implementations, depending on the location/position of the vertex 202 within the design space 201, the corresponding geometric shapes 212, 214, 216, 218 may be classified into various categories:
Diagonal Path 216: The four (4) vertices 202 of the design space 201 can be optimized as 1D variables within diagonal lines or paths 216 along O-O′, P-P′. In the exemplary implementation shown in FIGS. 1 and 2, these vertices are labeled d1, d2, d3, and d4.
Triangular Path 212: To accommodate corner cuts, neighboring vertices 202 near d1, d2, d3, and d4 can be optimized as 2D variables within triangular paths or shapes 212. In the exemplary implementation shown in FIGS. 1 and 2, these vertices are labeled a1 to a8.
Rectangular Path 214: To accommodate edge slots, vertices 202 adjacent to the triangular paths 212 can be optimized as 2D variables within rectangular paths or shapes 214. In the exemplary implementation shown in FIGS. 1 and 2, these vertices are labeled b1 to b8.
Straight Line Path 218: To accommodate slits, vertices 202 along the middle of the horizontal and vertical edges can be optimized as 1D variables along straight lines or straight line paths 218. In the exemplary implementation shown in FIGS. 1 and 2, these vertices are labeled c1 to c6.

For example, vertex d1 may be movable along a one-dimensional direction 204 (that is, along the diagonal path O-O′), vertex a1 may be movable along a two-dimensional direction 206 within a triangular shape or path 212, vertex b1 may be movable along a two-dimensional direction 206 within a rectangular shape or path 214, and vertex c1 may be movable along a one-dimensional direction 204.

Referring to FIG. 1, in some implementations, the methods may optimize the EM structure shape 200 to achieve one or more performance goals for the corresponding planar electromagnetic structure, for example, by moving (as indicated by the corresponding arrows 204, 206) and optimizing the location (also called “position”) of the variable vertices 202 of the shape 200 on a plane 203. In the optimization, the vertices 202 may be represented in a Cartesian coordinate system (wherein each vertex is represented as a (x, y) pair, that is, the distances of the vertex to a pair of perpendicular axes). It should be understood that other coordinate systems can be used, such as a polar coordinate system where each vertex is expressed as a (r, θ) pair, that is, r is the distance of the vertex to the origin and θ is the angle of the vertex-origin line with respect to a reference line. In some implementations, the optimization may be performed under one or more conditions, limitations, or restrictions, which will be described in more detail. The coordinates of the variable vertices 202 are optimized to achieve the desired one or more electromagnetic performance goals, with boundaries 208, 210 defined by the target frequency range to cover both lower and upper bands.

In some implementations, each of the plurality of geometric shapes 212, 214, 216, 218 comprises optimization boundaries determined based on design considerations as well as the target frequency range of the planar electromagnetic structure. The optimization boundaries for each geometric shape are defined to prevent overlapping, ensuring a clear and efficient design process. For example, the optimization boundaries of the triangular shapes 212 are set to avoid overlapping with the diagonal paths 216. Similarly, the optimization boundaries of the rectangular shapes 214 are set to avoid overlapping with the triangular shapes 212.

In some implementations shown in FIG. 2, an overall lower boundary 208 and upper boundaries 210 may be defined for the geometric shapes 212, 214, 216, 218, according to the target frequency range of operation. The optimization boundaries of each geometric shape can then be defined based on the overall lower boundary 208 and upper boundaries 210 as well as the geometric shapes of the neighboring vertices. This flexible boundary-setting approach allows for the design of slotted patches with tailored electromagnetic performance, achieving the target frequency range and characteristics. In other words, the method may move each variable vertex 202 along the respective directions 204, 206 within its boundaries to find a location thereof that may give rise to a shape 200 of the electromagnetic structure with one or more optimized performance measures. In the example shown in FIG. 2, each of the overall upper and lower boundaries 210 and 208 for the vertices 202 form a rectangular shape. In other implementations, other shapes of upper and lower boundaries 210 and 208 may be used, based on, for example, the fundamental frequency range.

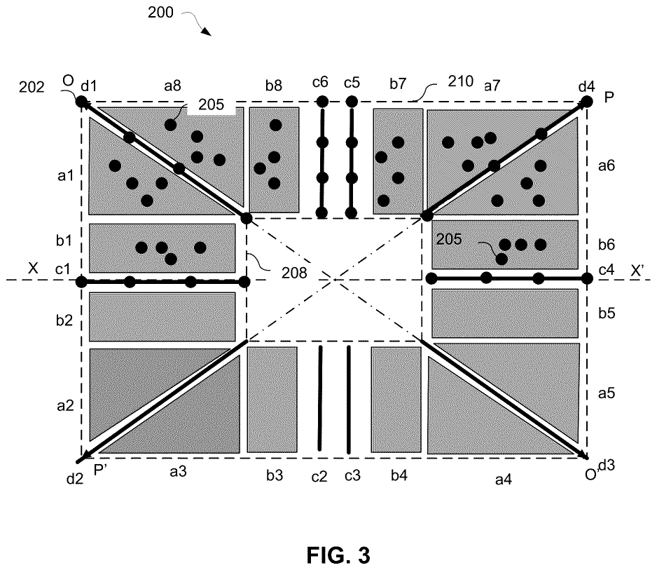

In some implementations shown in FIG. 3, the location/position of each of the variable vertices 202 may be selected from a plurality of candidates or samples 205 within a corresponding geometric shape 212, 214, 216, 218 within its respective optimization boundaries. In the exemplary implementation as shown in FIG. 3, the location/position of each variable vertex 202 may be selected from four (4) candidate values within its respective boundaries for optimization.

In some implementations, a plane of symmetry may be employed through one or both of the pair of perpendicular axes, which can reduce the total number of variables. For example, as shown in FIG. 3, the shape of the EM structure can be symmetrical with respect to the horizontal axis X-X′, which can generally reduce the total number of variables by half.

In some implementations, an “optimization variable” refers to a variable whose value can be varied, determined, or otherwise optimized for optimizing one or more performance measures of the electromagnetic structure 200. In some implementations, an “optimization parameter” refers to a parameter whose value can be used but may not be changed during the optimization process. An optimization parameter sometimes may also be called a “variable” although its value may not be changed during the optimization process.

For example, the plurality of vertices 202 may be categorized as either fixed vertex/vertices, or variable vertex/vertices (i.e., optimization variables). The location of a fixed vertex 202 may not be changed and may not be used in the optimization process. In some implementations, frequency parameters can be used as an input for the EM structure optimization, and the frequency parameter may be an optimization parameter whose value can be used but may not be changed during the optimization process.

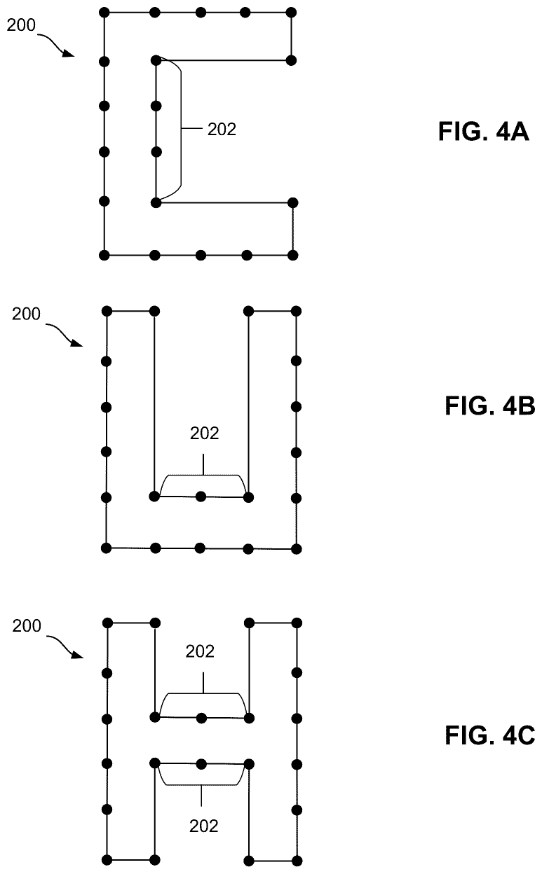

By using the above-described methods, randomness in the shape of patch 200 may be explored, optimization variables can be increased and not limited to template-based structures, which may offer a variety of benefits such as the ability to reduce unwanted (fundamental or higher) modes while also optimizing performance for specific desired modes required for certain applications. For example, random shapes (that is, shapes obtained through the introduction of randomness) may contribute to a variety of applications such as multiband and wideband applications. One or more slot shapes can be accommodated in the EM structure designs for enhanced performance. FIG. 4 illustrates some of common slot shapes that can be accommodated in the optimization of the EM structure according to some implementations, including such as C shape (FIG. 4(A)), U shape (FIG. 4(B)), and H shape (FIG. 4(B). As illustrated in FIG. 4, variable vertices 202 can be movable and optimized to accommodate corner cuts and slots of customized size at the patch edge in order to locate and satisfy circular polarization.

It should be understood that while FIGS. 1 to 3 illustrate some implementations of the vertices 202 and their geometric shapes 212, 214, 216, 218, the number of vertices 202, their types and/or other geometric shape segmentation may be implemented for the optimization of the EM structure. For example, the number and/or locations of variable vertices may be chosen to accommodate for one or more specific slots or slits, the primary patch may not start with a rectangular shape, and/or the geometric shapes of the variable vertices may not be limited to straight lines, triangular shapes, and/or rectangular shapes.

In some implementations, the method may use an AI model to optimize the shape of an electromagnetic structure 200. Any suitable AI model such as a deep learning or machine learning model may be used for electromagnetic shape optimization. The described methods outline a suitable data generation technique that can be implemented on a commercial electromagnetic software so that a machine learning model can be trained afterwards and an optimization algorithm can operate to obtain the desired one or more electromagnetic performances of the EM structure.

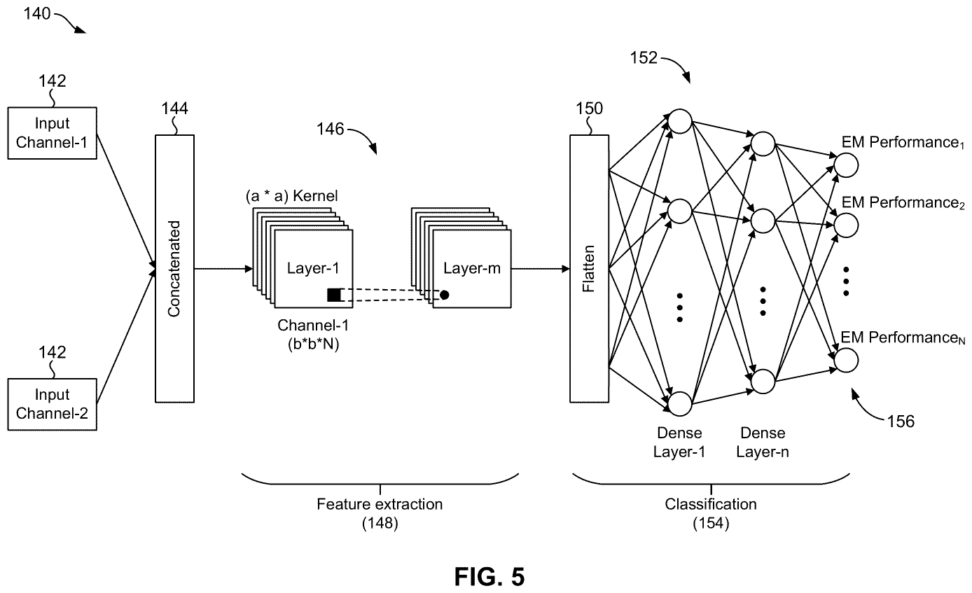

For example, in some implementations, the method may use a convolutional neural network (CNN) model, for example, to replace the computationally expensive EM model and may conduct above-described shape optimization. As those skilled in the art will appreciate, CNN has a great potential to imitate the electromagnetic behavior of any given structures. As shown in FIG. 5, the CNN model 140 receives a plurality of input channels 142, which may handle one or more of geometric variables such as the locations of the vertices 202 of the patch 200 and frequency parameters. In some implementations, different features of the EM structure such as vertices of the patch 200 and frequency parameters can be handled in different input channels 142 for ease of CNN modeling while the outputs can be any EM performance parameters, such as S-parameters. While two input channels are demonstrated in FIG. 5, it should be understood that more input channels can be used and other information such as location of the feed point (e.g., if the feed point is a variable), and/or substrate details may also be provided through the input channels 142.

The input channels 142 are concatenated (144) and then processed by a plurality of convolutional layers 146 for feature extraction 148. The extracted features are flattened (150) and then processed by a plurality of dense layers 152 for classification 154 to generate one or more EM performance measures such as the S-parameters (for example, the real and imaginary parts of one or more S-parameters) of the patch 200 as outputs 156.

In some implementations, with the CNN model 140, the method may use the genetic algorithm (GA) to optimize the electromagnetic shape 200 for achieving the desired circuit performance.

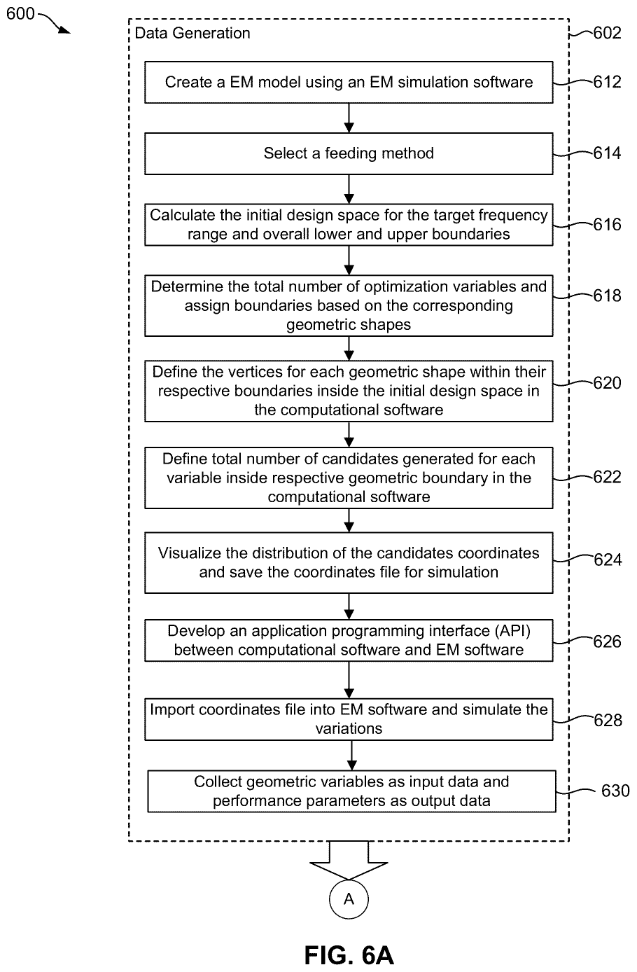

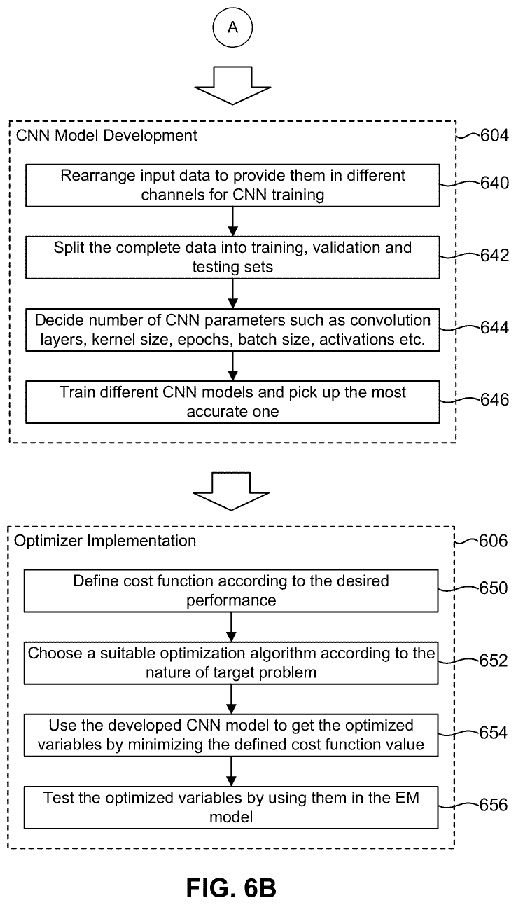

FIGS. 6A and 6B show a flowchart illustrating an example of the workflow 600 for designing an electromagnetic structure 200 using the described method, according to some implementations of this disclosure.

As shown, the workflow 600 may comprise three stages, including a data generation stage 602 (having steps 612 to 630), a CNN model development stage 604 (having steps 640 to 646), and an optimization implementation stage 606 (having steps 650 to 656).

In some implementations, the data generation stage 602 may use a full-wave electromagnetic simulation software (also denoted an “EM software”) such as CST Studio Suite® offered by Dassault Systèmes of Vélizy-villacoublay, France, high-frequency structure simulator (HFSS™) offered by Ansys®, Inc. of Pennsylvania, USA, FEKO® offered by Altair Engineering of Michigan, USA, and the like to develop the electromagnetic model of an electromagnetic structure with necessary and/or desired variables and boundaries thereof, so as to provide data for training the CNN model 140. It is understood that, in other implementations, other similar software may be used. In some implementations, the data generation stage 602 may employ an automatic data collection process, which may use a computational software such as Python, MATLAB, or the like to automatically prepare various value combinations of the variables related to the electromagnetic structure (for example, geometric variables such as the locations of the variable vertices 202 of the patch 200, frequency parameters, and/or the like), and automatically send the prepared value combinations of the variables and the desired distribution thereof to the EM software to allow the EM software to perform simulations. The simulation results may then be sent from the EM software to the computational software, which may be combined with the corresponding value combinations of the variables for use as training data for training the CNN model in the CNN model development stage 604. The trained CNN model may then be used in the optimization implementation stage 606 for designing electromagnetic structures.

In some implementations, in the data generation stage 602, an electromagnetic model of an electromagnetic structure is created (612) using a full-wave EM simulation software such as CST Studio Suite®, HFSS™, or FEKO®. At step 614, a feeding method may be selected, e.g., coaxial or microstrip, both of which are simple to implement. At step 616, the initial design space (also referred to as the initial patch shape, or primary patch) can be calculated by way of using e.g., design rules based on the target frequency range. The overall lower and upper boundaries 208, 210 of the design space can be determined according to the optimization boundary of the initial design space against fundamental mode. At step 618, the total number of optimization variables (e.g., variable vertices) are determined, and optimization boundaries are assigned based on their respective geometric shapes (e.g., triangles, rectangles, straight lines, and the like) as shown in FIG. 2. The total number of optimization variables may be chosen based on the candidate sampling criteria and total number of desired EM simulations. To reduce the total number of variables, a plane of symmetry may be employed through at least one of the pair of perpendicular axes of a coordinate system. For example, the EM structure may be designed to be symmetric with respect to a horizontal axis X-X′, which can generally reduce the total number of variables to half. In some implementations, the feed location may be considered as fixed.

In the computational software (e.g., Python) environment, the vertex for each geometric shape (e.g., triangle, rectangle, straight line, and the like) can be defined (620) within the respective boundaries inside the design space. As described, the boundaries are assigned ensuring no overlap between the various geometric shapes occupying the initial design space.

At step 622, the total number of candidates and their different coordinates can be generated for each variable vertex inside their respective geometric optimization boundary in the computational software. For instance, if m is the total number of variable vertices (each bounded by a corresponding geometric shape) and for each geometric shape there are n number of candidates provided for the corresponding variable vertex, the total number of variations is n×m.

At step 624, the distribution of the vertices can be visualized and the coordinate file of the plurality of candidates for the vertices can be saved for simulation. The computational software may write the combinations of the variable parameters (for example, including one or more of: parameters of frequency and the locations of the vertices) for all the simulations into a data file of desired format, which may be used as the input data for the CNN model 140.

In some implementations, the computational software may be used for performing the method for optimizing the shape of the electromagnetic structure, and the EM software may be used for generating and simulating the electromagnetic structure with the shape produced from the computational software. An application programming interface (API), e.g., a Python-CST API, between the computational software and the EM software may be developed (step 626) to automate simulations. The coordinate file of the plurality of candidates for the vertices can be imported (628) into the EM software to simulate all variations. The geometric variables used in the simulation may be collected (630) as input data for the CNN model 140 (to be used at step 646 for training the CNN model 140) and the performance parameters (for example, the scattering parameters (that is, the S parameters) may be extracted and saved. The performance parameters may be collected as output data for the CNN model 140 (to be used at step 646 for training the CNN model 140).

Referring to FIG. 6B, in the CNN model development stage 604, the collected input data may be rearranged and may be provided to the CNN model via different input channels for CNN training (step 640). In some implementations, the input data for the frequency parameters and the vertices' locations may be provided via separate input channels. The input data may further be partitioned into training data sets, validation data sets, testing data sets, or a combination thereof (step 642), and the values of various CNN parameters such as the number of convolution layers, the number of kernel size, the number of epochs, the number of batch size, the number of activations, and/or the like may be decided (step 644). After the settings at steps 640 to 644 are completed, different CNN models may be trained and the most accurate one may be selected (step 646).

As shown in FIG. 6B, in the optimizer implementation stage 606, a cost function may be defined according to the desired electromagnetic performance (step 650), and a suitable optimization algorithm may be selected according to the nature of the target problem (step 652). At step 654, the trained CNN model 140 may be used to obtain the optimized variables by minimizing the defined cost function value. At step 656, the optimized variables may be tested by applying them in the EM model. The electromagnetic structure 200 with an optimized shape may then be designed, and then may be sent to a manufacturing apparatus for fabrication (such as using etching, printing, or other suitable technologies). In some implementations, the electromagnetic structure can be used as at least a portion of a transmitter or a receiver.

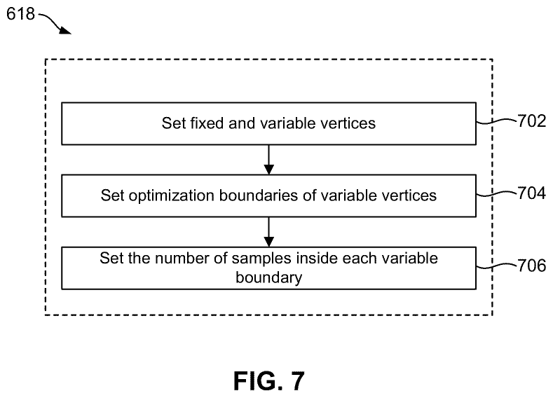

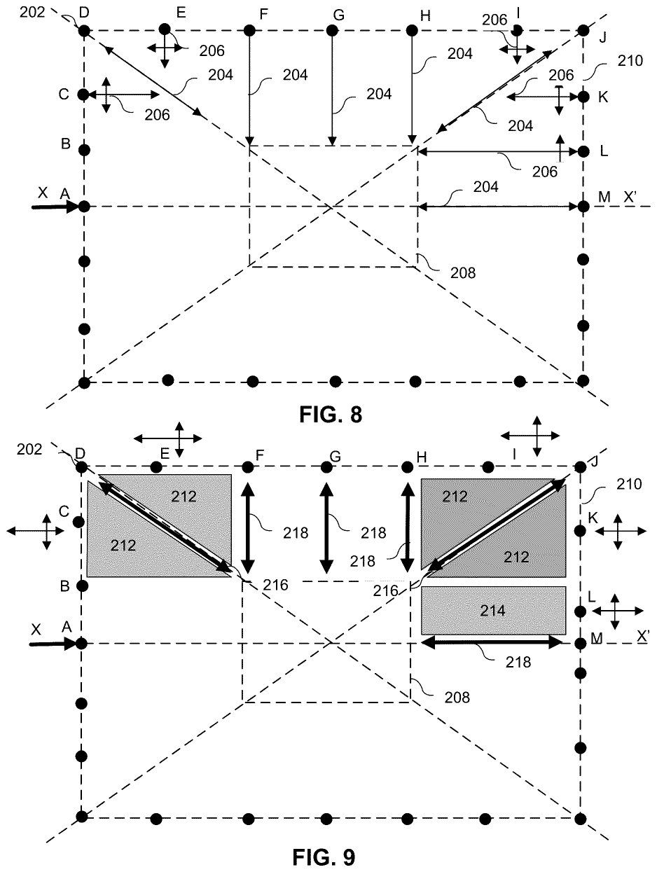

FIG. 7 illustrates the details of step 618 towards data generation for the designs of the EM structures. The step comprises setting (702) fixed and variable vertices 202. By way of an example and with reference to FIGS. 8 and 9, vertices A, B can be set as fixed vertices. Vertice A may be provided as the feed location as, e.g., the microstrip line port. Vertices C, D, E, F, G, H, I, J, K, L and M can be designated as variable vertices movable along their respective directions 204, 206 within corresponding geometric shapes 212, 214, 216, 218.

In the implementation as shown in FIGS. 8 and 9, the EM structure may be designed to be symmetric with respect to the horizontal axis X-X′, which can generally reduce the total number of variable vertices to half.

Optimization boundary of the variable vertices 202 can be set (704) that prevent overlapping with each other and based on the target frequency range. In the implementation as illustrated in FIGS. 8 and 9, the optimization boundary can be introduced comprising setting an overall lower boundary 208 and an overall upper boundary 210. In this implementation, vertices D, F, G, H, J and M are considered as 1D variables, while vertices C, E, I, K and L are considered as 2D variables.

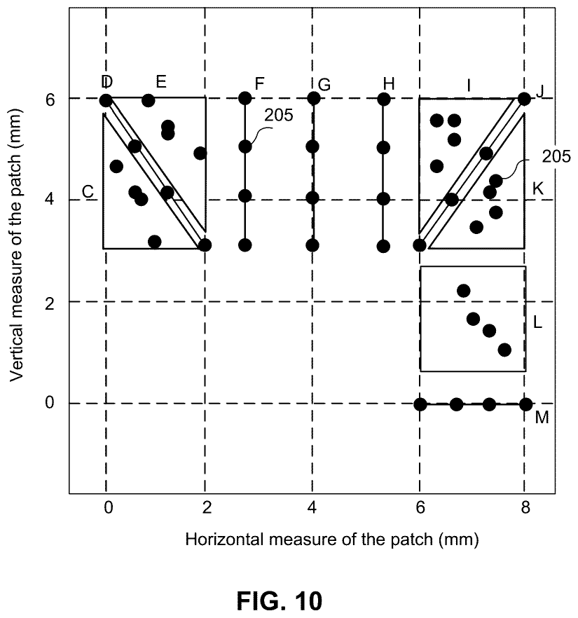

The number of candidates inside each variable's optimization boundary can be set at step 706. In some implementations, variable vertices are bound by their respective geometric shapes. For example, as described above, 2D variables can be bounded by their respective triangle shapes or rectangle shapes, while 1D variables can be bounded by the corresponding straight lines. In the exemplary implementation as shown in FIG. 10, four (4) candidates/samples can be assigned for each geometric shape.

In some implementations, the vertex 202 may be selected from candidates/samples randomly or evenly distributed within the corresponding geometric shape. In one exemplary example, the location/position of the vertex for a 1D variable may be selected from equidistant candidates within the range of the corresponding straight line 216, 218; and the location/position of the vertex for a 2D variable may be selected from randomly distributed candidates within the corresponding 2D geometric shape. For example and referring to FIG. 10, for each of one or more of vertices D, F, G, H, J, and M, the vertex may be selected from equidistant points in the range of the corresponding straight line 216, 218 (where two (2) out of the four (4) candidates may be end points of the range of the corresponding straight line 216, 218); and for each of one or more of vertices C, E, I, K, and L, the vertex may be selected from randomly distributed candidates within the corresponding 2D geometric shape. In some other implementations, the candidate/sample distribution may be revised/changed, for example, such that the feeding coordinates can be optimized in the revised range.

In the following, antenna examples are described, and the performances of the designed antennas are presented. In some implementations, designs of dual-band and wideband antennas operating in the X-band are focused to demonstrate the effectiveness of the described methods.

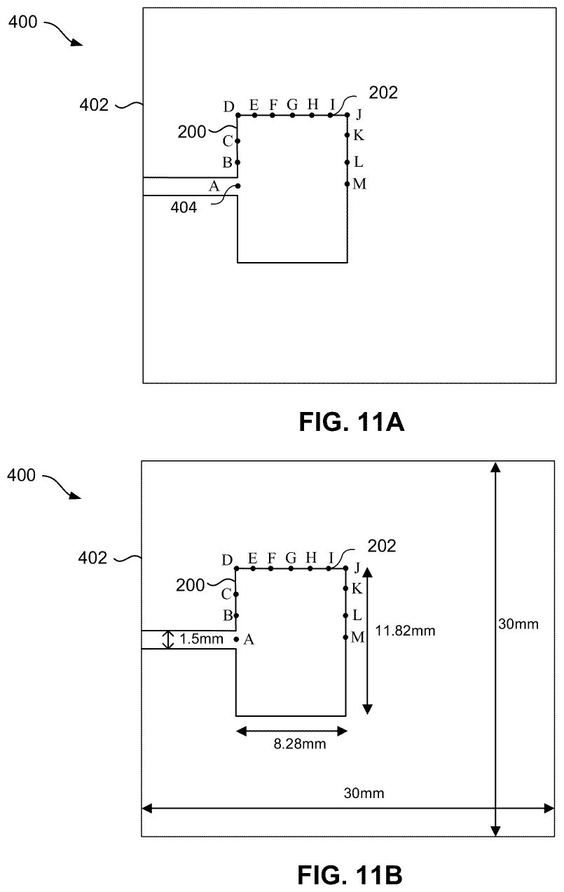

FIGS. 11A and 11B show an example of a patch antenna 400, which may comprise a metallic patch 200 on a substrate 402. In some implementations, the substrate 402 may be an Aerowave™ 300 substrate (dielectric constant, Dₖ=3) of 60 mil thickness. The antenna 400 may be fed by a 50Ω matched microstrip line. As shown in this implementation of FIG. 11B, the substrate dimensions may be 30 m by 30 mm, and the metallic patch 200 has primary dimensions of 11.82 mm by 8.28 mm and the feed line width is 1.5 mm.

The primary patch shape modeled in EM software e.g., CST Studio Suite 2022 can be illustrated in FIG. 9, which provides the segmentation of the design space. As described, this exemplary implementation uses a horizontal symmetry plane (X-X′) to reduce the total number of variable vertices.

Referring to FIGS. 8 and 9, the shape of the metallic patch 200 may comprise a plurality of vertices 202 which defines a polygon. Amongst the plurality of vertices 202, eleven (11) variable vertices are marked (at step 702) as C to M. Vertex A is kept constant to maintain the connection of the microstrip feedline to the vertex throughout the design and optimization process. Each of the eleven (11) variable vertices C to M may be variable within a corresponding geometric shape for optimization. Each of the two corner vertices, D and J, can be allowed to vary diagonally along a diagonal path 216. The neighboring four (4) vertices—C, E, I, and K—can be permitted to vary two-dimensionally within a respective triangle 212. Vertex L is variable two-dimensionally within a rectangular 214. The remaining vertices—F, G, H, M—are variable along the respective straight lines 218.

To cover the target operating frequency for example, between 8 gigahertz (GHz) to 12 GHz, the overall upper boundary 210 and lower boundary 208 can be defined (step 704). The optimization boundaries of the respective geometric shapes can be subsequently defined based on the upper boundary 210 and the lower boundary 208. In some implementations, the optimization boundaries for different vertices can also be adjusted according to the variety of possible slotted structures to be accommodated in the EM structure.

Referring to FIG. 10, a plurality of (e.g., four (4)) candidates can be generated (step 706) for each variable vertex, using the computational software, e.g., a Python script. The results are a total of 4¹¹=4,194,304 design combinations or variations. FIG. 10 displays an example of the distribution of the candidates generated at the upper half of the X-X′ plane.

In some implementations, the location of the feed point 404 in local coordinates may also be an optimization variable, along with the variable vertices 202, for achieving better impedance matching in different desired performances. In some implementations, antenna structures (that is, the antenna structures corresponding to all or a subset of combinations of locations of the eleven (11) vertices 202) may be simulated in a frequency range e.g., 8 GHz to 12 GHz so that the higher order modes may be considered for multiband and wideband applications.

In some implementations, frequency may be considered as an input optimization parameter (whose value may be used in optimization but would not be changed or optimized) of the CNN model 140 so that during the optimization phase, the antenna structure may be optimized against various frequency responses. In some implementations, antenna performances may be calculated for a fixed/predetermined number of frequency points, for example, eighty (80) frequency points in a predefined range such as 8 GHz to 12 GHz.

To reduce EM simulation time required for the variations, a subset of e.g. 16,000 structures can be randomly selected using the computational software and EM simulations can be performed on the randomly selected structures across a number of frequency points within the target operating frequency range (e.g., eighty (80) frequency points ranging from 8 GHz to 12 GHz). This process can then generate a total of 1,280,000 samples of EM data.

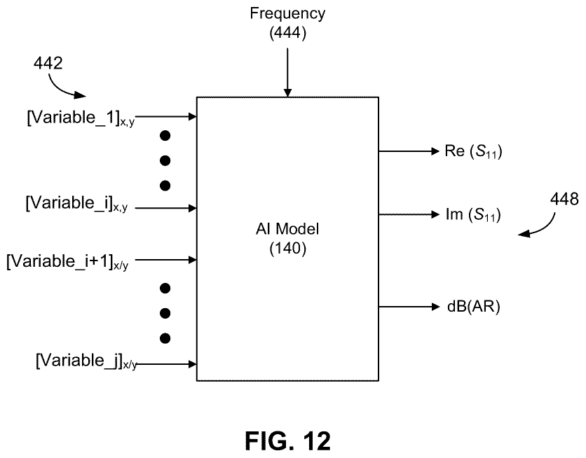

FIG. 12 is a schematic diagram showing inputs and outputs of the AI model 140, according to some implementations of this disclosure. As shown, the AI model 140 may receive a plurality of inputs 442 including the coordinates, for example, Cartesian coordinates x and y of the plurality of vertices, for example, eleven (11) variable vertices 202. Amongst the eleven variable vertices 202, at least one to i (i is an integer and 1≤i≤11) number of variable vertices are 2D variable(s), denoted as [Variable_1]_{x,y}, . . . [Variable_i]_{x,y}. The coordinates of these 2D variable vertices can vary with respect to two dimensions independently and the 2D variation can be represented by the pair of coordinates (e.g., a pair of Cartesian coordinates (x, y)). The balance of the eleven variable vertices 202 can be 1D variable(s) [Variable_i+1]_{x/y}, . . . [Variable_j]_{x/y} (j is an integer and 0≤j≤10) where the coordinates of these vertices can vary with respect to one dimension, e.g., along one of the two perpendicular axes of a coordinate system (such as a Cartesian coordinate system), or along a straight line. Because for 1D variation, the variations of the pair of coordinates are correlated, the 1D variation can be represented by one of the pair of coordinates (e.g., one of the pair of Cartesian coordinates (x/y)).

In some implementations, each variable vertex may be represented in a Cartesian coordinate system having a coordinate pair (x, y). When the variable vertex is a 1D variable, the variation of the coordinates can be represented by one of the two coordinates x or y. For example, for vertex D, the Y axis coordinate value Dy of the vertex can be formulated through (by way of its correlation to) the X axis coordinate value Dₓ of the vertex, based on the intended locus of the diagonal line 216. As such, each 1D variable can be represented with one of the coordinate values being a variable for optimizing one or more performance measures of the electromagnetic structure 200. For example, for 1D variable vertex D, Dₓ can represent the variable for the D vertex coordinates; Similarly, the X axis coordinate value Jₓ can represent the variable for the J vertex coordinates. As shown in FIGS. 8-10, the optimization boundary for vertex M shares the same X axis coordinate boundary as that of vertex J.

Accordingly, the boundary for a 1D variable can be represented as a range of one of the coordinate values. For example, in the Cartesian coordinate system, the boundary for D vertex can be set as Dₓ=[0, 2]; the boundary for J vertex can be set as Jₓ=[6.28, 8.28]; the boundary for M vertex can be set as Mₓ=[6.28, 8.28]; and the boundary for H, G, F vertices can be set as [3.03, 5.91], where [v, q] is a range between v and q inclusive.

Because for each 2D variable the coordinates are variable with respect to two dimensions independently, each 2D variable vertex can be represented by the coordinate pair (x, y), both of which are variable independently for optimizing one or more performance measures of the electromagnetic structure 200. For example, some candidates for the 2D variables can be represented as
vertex candidate C₁ has a coordinate pair (x_{C}=0, y_{C}=2.95),
vertex candidate C₂ has a coordinate pair (x_{C}=0, y_{C}=4.925),
vertex candidate C₃ has a coordinate pair (x_{C}=1.8, y_{C}=2.95),
vertex candidate E₁ has a coordinate pair (x_{E}=0.5, y_{E}=5.91),
vertex candidate E₂ has a coordinate pair (x_{E}=2.07, y_{E}=5.91),
vertex candidate E₃ has a coordinate pair (x_{E}=2.07, y_{E}=3.2),
vertex candidate I₁ has a coordinate pair (x_{I}=6.35, y_{I}=5.91),
vertex candidate I₂ has a coordinate pair (x_{I}=7.59, y_{I}=5.91),
vertex candidate I₃ has a coordinate pair (x_{I}=6.35, y_{I}=3.2),
vertex candidate K₁ has a coordinate pair (x_{K}=8.28, y_{K}=5.85),
vertex candidate K₂ has a coordinate pair (x_{K}=8.28, y_{K}=3),
vertex candidate K₃ has a coordinate pair (x_{K}=6.35, y_{K}=3),
vertex candidate L₁ has a coordinate pair (x_{L}=6.35, y_{L}=0.5),
vertex candidate L₂ has a coordinate pair (x_{L}=8.28, y_{L}=0.5),
vertex candidate L₃ has a coordinate pair (x_{L}=8.28, y_{L}=2),
vertex candidate L₄ has a coordinate pair (x_{L}=6.35, y_{L}=2),

Then, the optimization variables for the eleven (11) variable vertices may be represented as x_{C}, y_{C}, X_{D}, X_{E}, Y_{E}, X_{F}, X_{G}, X_{H}, X_{I}, Y_{I}, X_{J}, X_{K}, Y_{K}, X_{L}, Y_{L}, and x_{M}. Accordingly, a 4-by-4 matrix containing the eleven (11) optimization variables for input channel-1 shown in FIG. 13, can be presented as a 4-by-4 matrix as follows:

$$[ \begin{matrix}{x}_{C} & {y}_{C} & {x}_{E} & {y}_{E} \\ {x}_{I} & {y}_{I} & {x}_{K} & {y}_{K} \\ {x}_{L} & {y}_{L} & {x}_{D} & {x}_{F} \\ {x}_{G} & {x}_{H} & {x}_{J} & {x}_{M}\end{matrix} ]$$

The AI model 140 may also receive a value of the operation frequency 444 as an optimization parameter. The output 448 of the AI model 140 may be one or more of the return loss S₁₁ (which may indicate how much power is reflected back at the antenna port due to mismatch from the transmission line) from a full-wave EM simulation model, which is shown in the form of the real and imaginary parts Re(S₁₁) and Im(S₁₁) thereof, and/or an AR of the EM structure, which may indicate the circular polarization characteristics.

In some of the above implementations, a computational software and an EM software are used for designing the electromagnetic structure with an optimized shape under one or more conditions such as the target frequency band. The designed electromagnetic structure may then send to a manufacturing apparatus for fabrication.

FIG. 13 shows the CNN model 140 used in this example.

In some implementations, input channel-1 may contain the 4-by-4 matrix as patch information for the eleven (11) variable vertices as shown above.

More specifically, input channel-1 processes the patch vertices as a 4×4 matrix, while input channel-2 handles the frequency parameter as a scalar input. These two inputs are augmented to match the same size and then concatenated along the final dimension before being passed into the CNN's convolutional layer.

The CNN model 140 in this example may comprise three (3) convolutional layers 146 having 256, 128 and 64 neurons, respectively, and three (3) fully connected (dense) layers 152 also having 256, 128 and 64 hidden neurons, respectively. These values of convolutional layers, neurons, connected layers, and/or the like may provide the optimal model in terms of accuracy and training time. In some other implementations, these values may be revised or changed such that the optimal model in terms of accuracy and training time is maintained/improved.

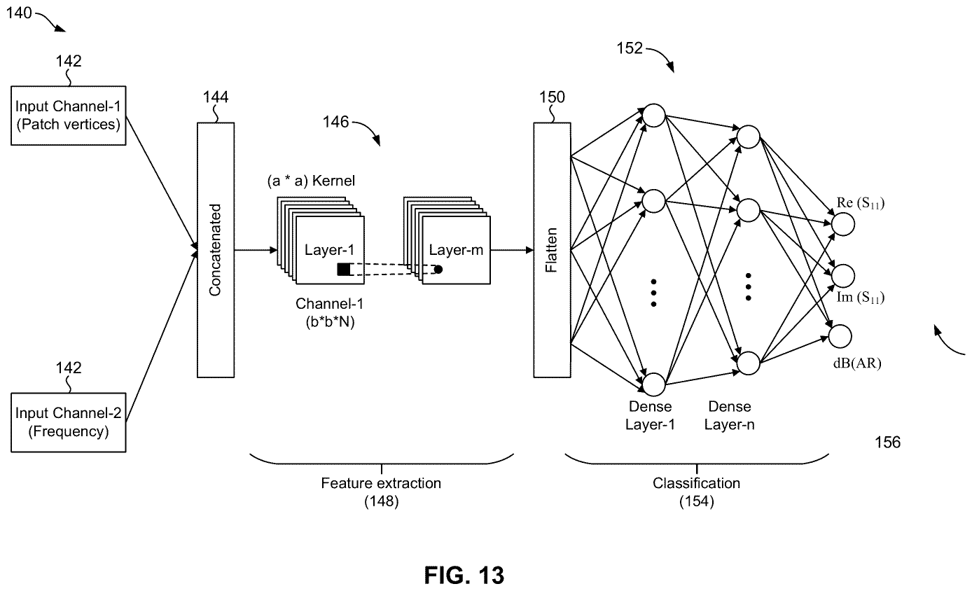

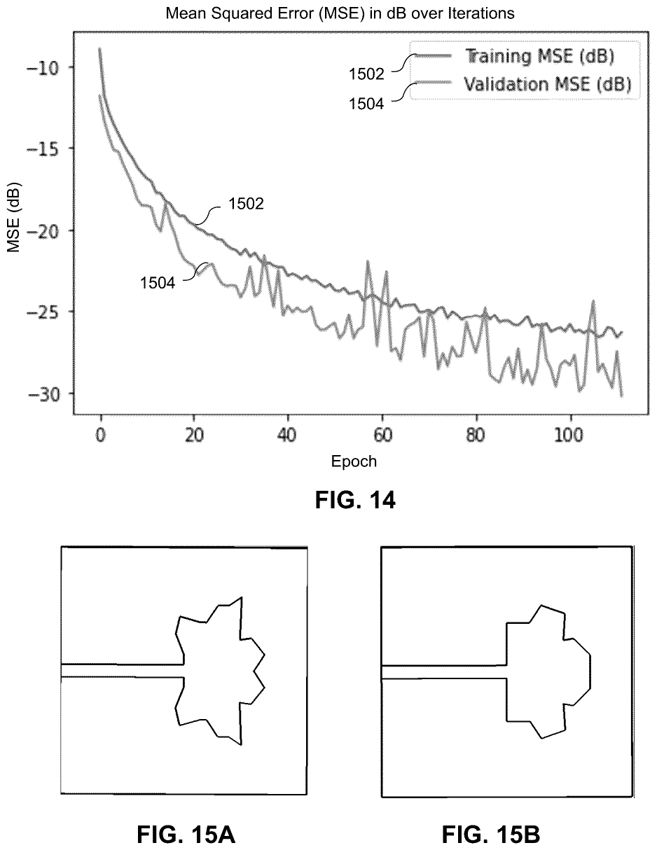

The output of the network provides both the real and imaginary components of the antenna's S₁₁-parameters, as well as an AR of the EM structure. FIG. 14 illustrates the MSE vs epoch convergence curve. As can be seen from the training MSE curve 1502 and the validation MSE curve 1504, after 100 epochs, the model achieves a mean squared error (MSE) of −25 decibels (dB), demonstrating sufficient accuracy for reliable antenna characterization.

In some implementations, after the successful development of the CNN model 140 with high accuracy (that is, MSE is −25 dB), the genetic algorithm (GA) optimizer may be used to obtain the optimized variables (e.g., the patch vertices) based on the desired antenna performance. The obtained electromagnetic structure with the optimized shape may be suitable for operation in various transverse modes such as transverse magnetic (TM) modes, transverse electric (TE) modes, or both the TM and the TE modes. The electromagnetic structure with the optimized shape may also be suitable for operation in a single transverse mode or a plurality of transverse modes in a plurality of frequency bands.

In some implementations, the optimization process is to minimize (step 654) a predefined cost function, which can be constructed around important performance parameters of the antenna. For example, one desired performance parameter can be the return loss (RL) within the operating band. For a multiband antenna, the objective can be to ensure that the S₁₁ response remains below a predetermined or predefined threshold (e.g., −10 dB) across all designated frequency bands. The cost function K can be defined in equation (1), where each band—Band₁, Band₂, . . . , Band_{N}—spans a specific frequency range.

$$K = max [ {( {S}_{11} )}_{{Band}_{1}} , - RL ] + max [ {( {S}_{11} )}_{{Band}_{2}} , - RL ] + … + max [ {( {S}_{11} )}_{{Band}_{N}} , - RL ] \qquad ( 1 )$$

where (S₁₁)_{Band} is the S₁₁ response of the corresponding band and RL represents the predetermined or predefined threshold of the return loss.

To design dual-band antennas, the cost function in (1) incorporates terms related to both the first and second frequency bands of the antennas. The first band spans from f₁ to f₂, while the second band spans from f₃ to f₄. For the design of wideband antennas, only the first term of the cost function in (1) may be required, as the design focuses on a single continuous operating band spanning from f₁ to f₂.

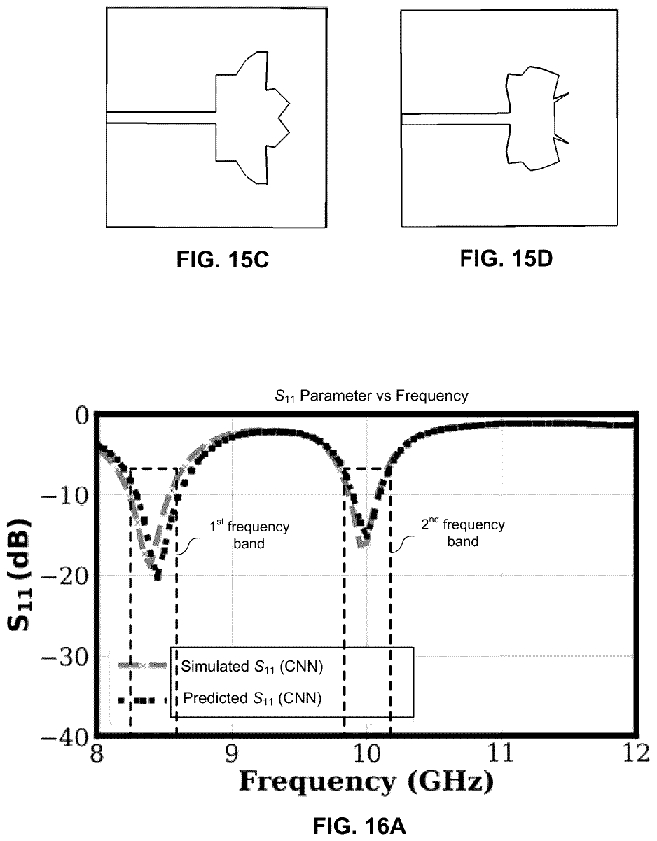

For example, FIGS. 15A to 15D show four optimized antenna structures for different applications, wherein antenna-1 (FIG. 15A) is optimized to have a dual-band performance with a frequency range of a first band between f₁=8.25 GHz and f₂=8.55 GHZ, and a second band between f₃=9.85 GHz and f₄=10.10 GHz, antenna-2 (FIG. 15B) is optimized for dual-band performance in the frequency range of a first band between f₁=8.50 GHz and f₂=8.80 GHz, and a second band between f₃=10.70 GHz and f₄=11.05 GHz. Antenna-3 (FIG. 15C) is optimized for wideband performance in the frequency range of between f₁-8.80 GHz and f₂=9.75 GHz; and antenna-4 (FIG. 15D) is optimized for wideband performance in the frequency range of between f₁=10.25 GHz and f₂=11.93 GHZ. The wideband antenna-3 and antenna-4 have an impedance bandwidth of 10-15%.

The optimized variables obtained by the GA algorithms for four different desired antenna performances are given in Table 1. The optimized parameters from Table 1 are used to design the four antennas targeting dual-band or wideband performance.

TABLE 1
OPTIMIZED GEOMETRIC VARIABLES FOR ANTENNAS OF DIFFERENT APPLICATIONS
(in mm)

| Antenna | Cₓ | C_{y} | Dₓ | Eₓ | E_{y} | F_{y} | G_{y} | H_{y} | Iₓ | I_{y} | Jₓ | Kₓ | K_{y} | Lₓ | L_{y} | Mₓ |
|---|---|---|---|---|---|---|---|---|---|---|---|---|---|---|---|---|
| Dual | −1 | 4.5 | −0.5 | 2 | 5.92 | 5.91 | 8 | 8 | 7 | 9 | 7 | 8 | 4 | 10 | 2 | 9 |
| Band-1 | | | | | | | | | | | | | | | | |
| Dual | 0 | 4.5 | 0 | 2 | 5.90 | 5.91 | 8 | 7.5 | 7 | 7 | 7 | 8 | 4 | 10 | 2 | 10 |
| Band-2 | | | | | | | | | | | | | | | | |
| Wide | 0 | 4.5 | 0 | 2 | 5.89 | 5.91 | 8 | 5.52 | 7 | 9 | 7 | 8 | 4 | 10 | 2 | 8 |
| Band-1 | | | | | | | | | | | | | | | | |
| Wide | −0.5 | 4.5 | −0.2 | 1.66 | 6.00 | 7.20 | 7 | 6.5 | 6.8 | 6 | 6 | 8.2 | 3.5 | 6 | 2.2 | 6 |
| Band-2 | | | | | | | | | | | | | | | | |

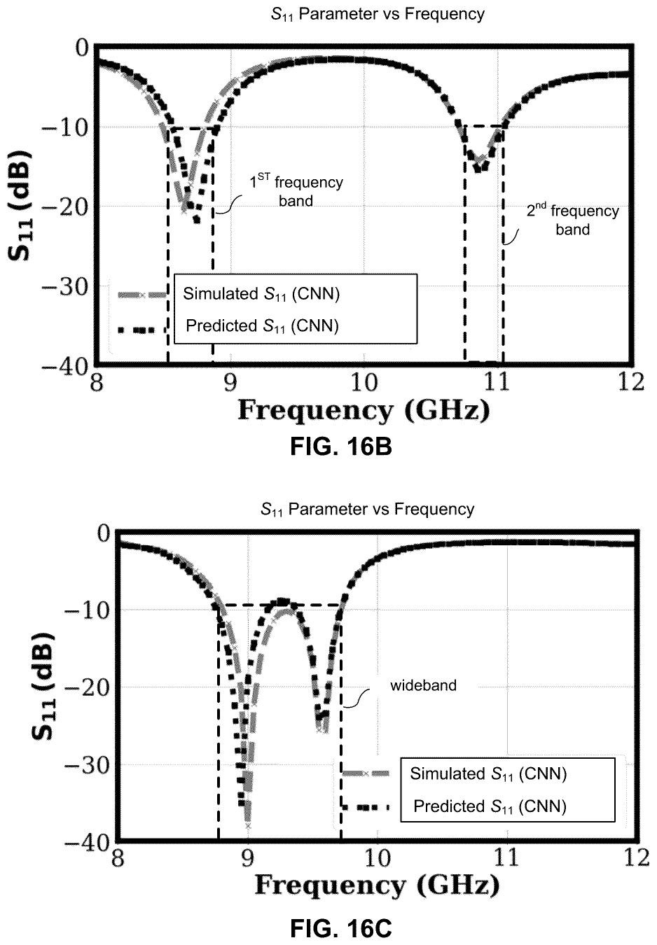

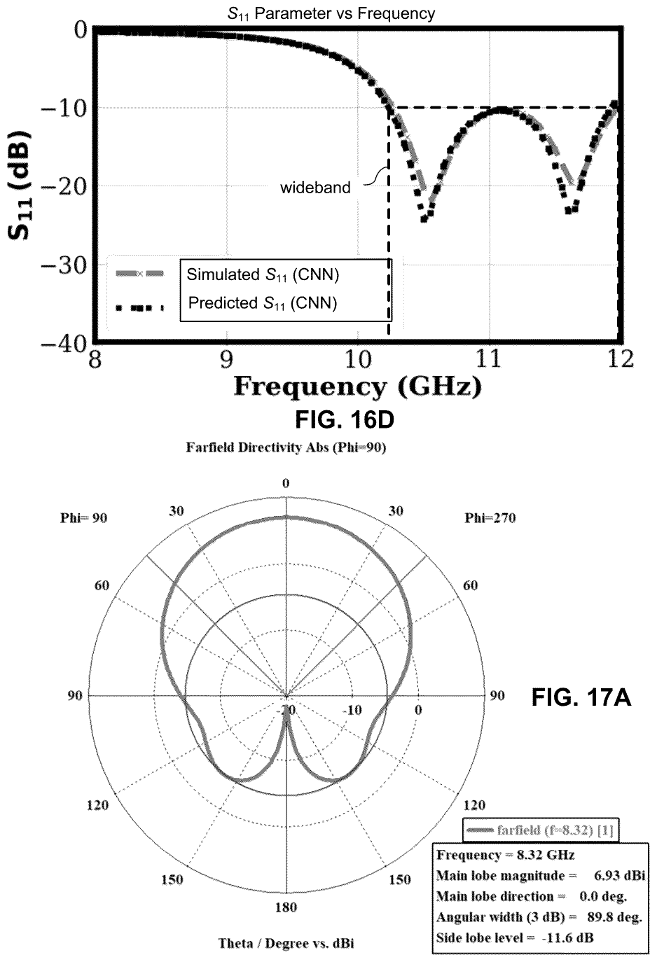

FIGS. 16A to 16D are plots showing the CNN and EM model calculated S₁₁ parameters for the antennas shown in FIGS. 15A to 15D, respectively. As shown in FIG. 16A, the antenna shown in FIG. 15A is suitable for operation in the dual frequency bands, where the first band has a center frequency f_{c}=8.3 GHz with a fractional bandwidth (FBW) of 4%; and the second band has a center frequency f_{c}=9.9 GHZ with an FBW of 4%. The RL level is equal or smaller than 10 dB in the two frequency bands as optimized. As shown in FIG. 16B, the antenna shown in FIG. 15B is suitable for operation in the dual frequency bands, where the first band has a center frequency f_{c}=8.6 GHz with a fractional bandwidth (FBW) of 4%; and the second band has a center frequency f_{c}=11.0 GHz with an FBW of 4%. The RL level is equal or smaller than 10 dB in the two frequency bands as optimized. FIG. 16C shows that the antenna shown in FIG. 15C is suitable for operation in the band between 8.8 GHz and 9.6 GHz with a fractional bandwidth (FBW) of 10%. FIG. 16D shows that the antenna shown in FIG. 15D is suitable for operation in the band between 10.45 GHz and 12.10 GHz with a fractional bandwidth (FBW) of 15%. For both wideband antennas shown in FIGS. 15C and 15D, the RL level is equal or smaller than 10 dB in the frequency band as optimized.

FIGS. 15 and 16 show that despite similar geometries, their S₁₁ responses can vary to a large extent. For example, a 0.25 GHz frequency shift can be observed between the design of FIG. 15A and FIG. 15B, despite their similarity. Further, FIG. 15A and FIG. 15C share a similar design, however, the antenna shown in FIG. 15A operates as a dual-band antenna, while the antenna shown in FIG. 15C operates as a wideband antenna. As can be seen from such results, minor changes in the patch vertex coordinates can greatly affect performance, enabling versatile antenna designs for various applications.

In some implementations, the method may be repeatedly performed with same input variables to obtain a plurality of optimized shapes for the electromagnetic structure, and then a selection is made from the plurality of optimized shapes based on the application or use case to choose a shape for the electromagnetic structure that best meets the requirements of the application or use case.

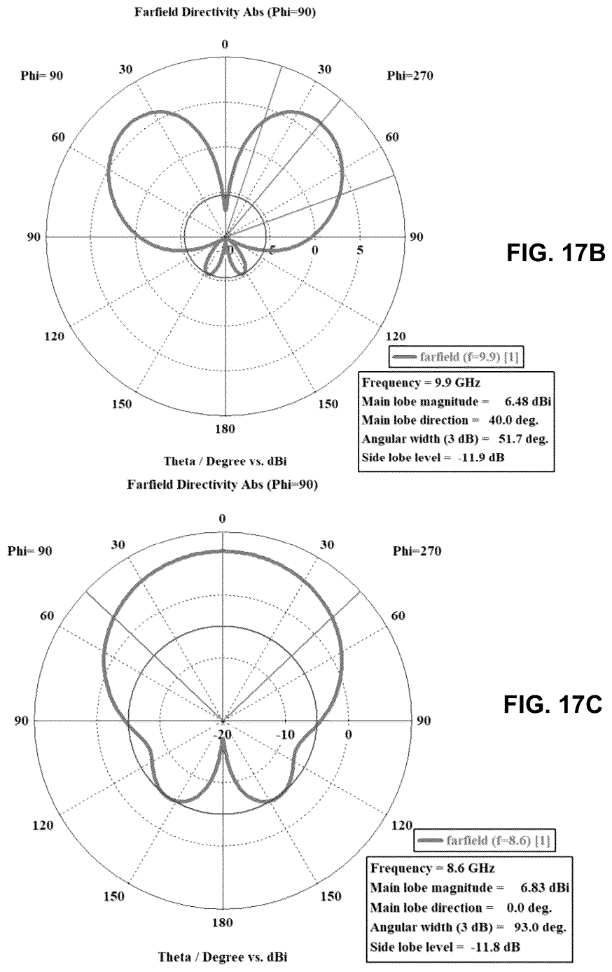

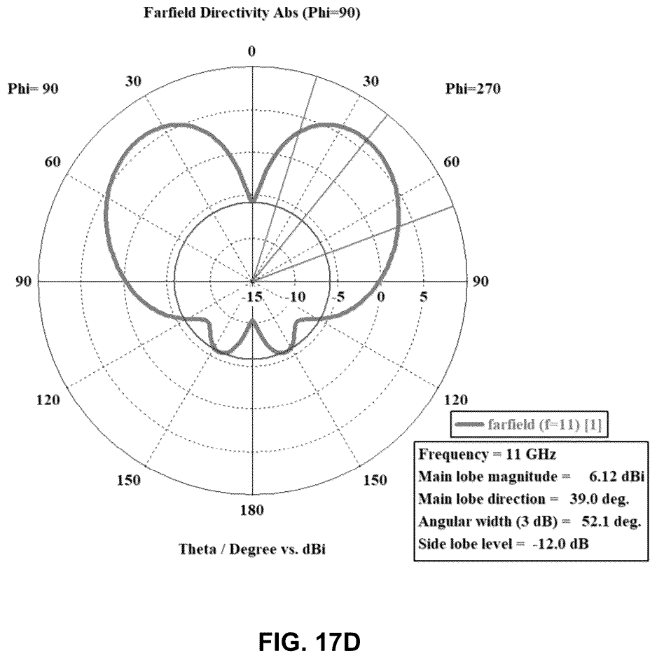

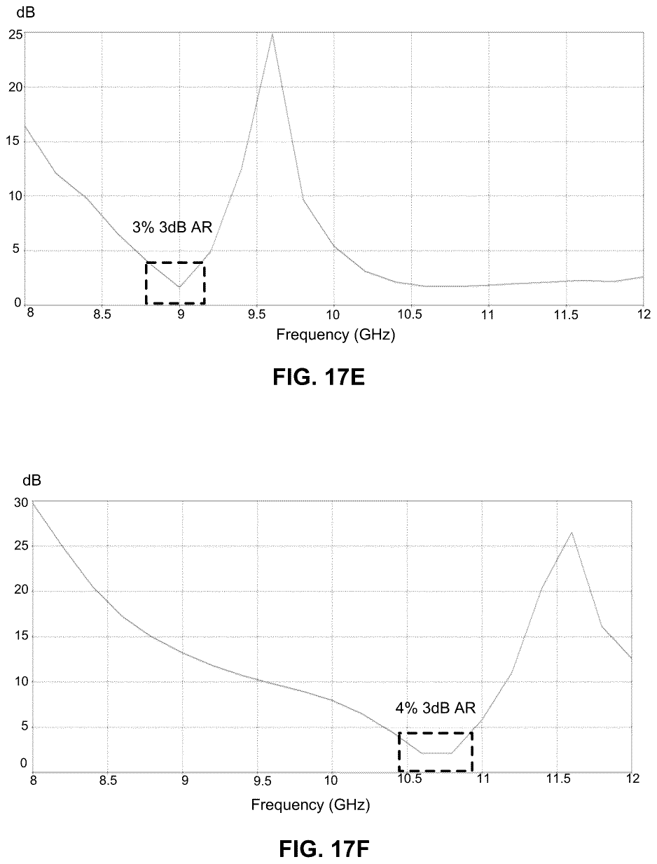

FIGS. 17A and 17B are plots showing the far-field radiation patterns at center frequencies of the dual frequency bands of the antenna shown in FIG. 15A; and FIGS. 17C and 17D are plots showing the far-field radiation patterns at center frequencies of the dual frequency bands of the antenna shown in 15B. More specifically, FIG. 17A shows the far-field radiation pattern at a center frequency of 8.32 GHz of the first frequency band for the designed antenna shown in FIG. 15A, and FIG. 17A shows the far-field radiation pattern at a center frequency of 9.9 GHz of the second frequency band for the designed antenna shown in FIG. 15A. FIG. 17C shows the far-field radiation pattern at a center frequency of 8.6 GHz of the first frequency band for the designed antenna shown in FIG. 15B, and FIG. 17D shows the far-field radiation pattern at a center frequency of 11 GHz of the second frequency band for the designed antenna shown in FIG. 15B.

It can be appreciated that the methods described in the implementations provide EM structure designs that can optimize other performance measures of the electromagnetic structure parameters, such as AR, enabling versatile designs satisfying circular polarization. FIG. 17E and FIG. 17F are plots showing the AR of the wideband antennas shown in FIG. 15C and FIG. 15D, respectively. FIG. 17E shows a 3% 3 dB AR within the frequency band between 8.8 GHz and 9.6 GHz; and FIG. 17F shows a 4% 3 dB AR within the frequency band between 10.45 GHz and 12.10 GHz.

In various implementations, the computational software and EM software may be executed by different computing devices or by the same computing device. Such computing devices may be any suitable computing devices in any suitable form, such as server computers, desktop computers, laptop computers, tablets, smartphones, Personal Digital Assistants (PDAs), and/or the like. Such computing devices may be standalone computing devices that are not connected with other computing devices, or may be a part of a computer network system.

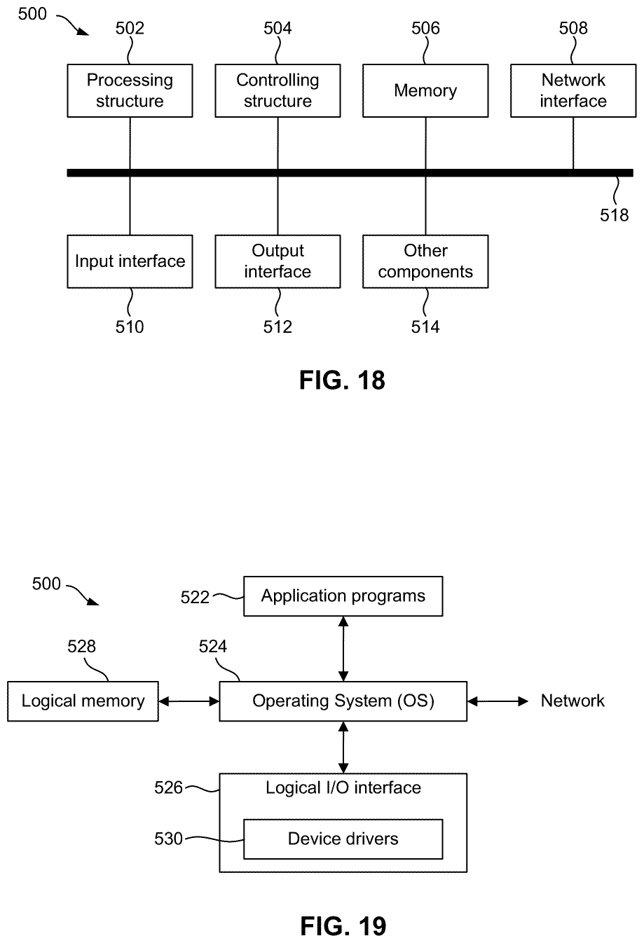

For example, FIG. 18 is a schematic diagram showing an example of the hardware structure of a computing device that may be used for executing the computational software and/or EM software. As shown, the computing device 500 may comprise one or more of a processing structure 502, a controlling structure 504, one or more non-transitory computer-readable memory or storage devices or media 506, a network interface 508, an input interface 510, and an output interface 512, functionally interconnected by a system bus 518. The computing device 500 may also comprise other components 514 coupled to the system bus 518.

In some implementations, the processing structure 502 may be one or more single-core or multiple-core computing processors, generally referred to as central processing units (CPUs), such as INTEL® microprocessors (INTEL is a registered trademark of Intel Corp., Santa Clara, CA, USA), AMD® microprocessors (AMD is a registered trademark of Advanced Micro Devices Inc., Sunnyvale, CA, USA), ARM® microprocessors (ARM is a registered trademark of Arm Ltd., Cambridge, UK) manufactured by a variety of manufactures such as Qualcomm of San Diego, California, USA, under the ARM® architecture, NVIDIA processor, or the like. When the processing structure 502 comprises a plurality of processors, the processors thereof may collaborate via a specialized circuit such as a specialized bus or via the system bus 518.

In some implementations, the processing structure 502 may also comprise one or more real-time processors, programmable logic controllers (PLCs), microcontroller units (MCUs), μ-controllers (UCs), specialized/customized processors, hardware accelerators, and/or controlling circuits (also denoted “controllers”) using, for example, field-programmable gate array (FPGA) or application-specific integrated circuit (ASIC) technologies, and/or the like. In some implementations, the processing structure includes a CPU (otherwise referred to as a host processor) and a specialized hardware accelerator which includes circuitry configured to perform computations of neural networks such as tensor multiplication, matrix multiplication, and the like. The host processor may offload some computations to the hardware accelerator to perform computation operations of neural network. Examples of a hardware accelerator include a graphics processing unit (GPU), Neural Processing Unit (NPU), and Tensor Process Unit (TPU). In some implementations, the host processors and the hardware accelerators (such as the GPUs, NPUs, and/or TPUs) may be generally considered processors.

In some implementations, the processing structure 502 may comprise necessary and/or desired circuitries implemented using technologies such as electrical and/or optical hardware components for executing one or more processes, as the design purpose and/or the use case maybe. For example, the processing structure 502 may comprise logic gates implemented by semiconductors to perform various computations, calculations, and/or processings. Examples of logic gates include AND gate, OR gate, XOR (exclusive OR) gate, and NOT gate, each of which takes one or more inputs and generates or otherwise produces an output therefrom based on the logic implemented therein. For example, a NOT gate receives an input (for example, a high voltage, a state with electrical current, a state with an emitted light, or the like), inverts the input (for example, forming a low voltage, a state with no electrical current, a state with no light, or the like), and output the inverted input as the output.

While the inputs and outputs of the logic gates are generally physical signals and the logics or processing thereof are tangible operations with physical results (for example, outputs of physical signals), the inputs and outputs thereof are generally described using numerals (for example, numerals “0” and “1”) and the operations thereof are generally described as “computing” (which is how the “computer” or “computing device” is named) or “calculation”, or more generally, “processing”, for generating or producing the outputs from the inputs thereof.

Sophisticated combinations of logic gates in the form of a circuitry of logic gates, such as the processing structure 502, may be formed using a plurality of AND, OR, XOR, and/or NOT gates. Such combinations of logic gates may be implemented using individual semiconductors, or more often be implemented as integrated circuits (ICs).

A circuitry of logic gates may be “hard-wired” circuitry which, once designed, may only perform the designed functions. In this example, the processes and functions thereof are “hard-coded” in the circuitry.

With the advance of technologies, it is often that a circuitry of logic gates such as the processing structure 502 may be alternatively designed in a general manner so that it may perform various processes and functions according to a set of “programmed” instructions implemented as firmware and/or software and stored in one or more non-transitory computer-readable storage devices or media or medium. In this example, the circuitry of logic gates such as the processing structure 502 is usually of no use without meaningful firmware and/or software.

Of course, those skilled the art will appreciate that a process or a function (and thus the processor 502) may be implemented using other technologies such as analog technologies.

Referring again to FIG. 18, the controlling structure 504 may comprise one or more controlling circuits, such as graphic controllers, input/output chipsets and the like, for coordinating operations of various hardware components and modules of the computing device 500.

The memory 506 may comprise one or more storage devices or media accessible by the processing structure 502 and the controlling structure 504 for reading and/or storing instructions for the processing structure 502 to execute, and for reading and/or storing data, including input data and data generated by the processing structure 502 and the controlling structure 504. The memory 506 may be volatile and/or non-volatile, non-removable or removable memory such as RAM, ROM, EEPROM, solid-state memory, hard disks, CD, DVD, flash memory, or the like.

The network interface 508 may comprise one or more network modules for connecting to other computing devices or networks through the network 108 by using suitable wired or wireless communication technologies such as Ethernet, WI-FI® (WI-FI is a registered trademark of Wi-Fi Alliance, Austin, TX, USA), BLUETOOTH® (BLUETOOTH is a registered trademark of Bluetooth Sig Inc., Kirkland, WA, USA), Bluetooth Low Energy (BLE), Z-Wave, Long Range (LoRa), ZIGBEE® (ZIGBEE is a registered trademark of ZigBee Alliance Corp., San Ramon, CA, USA), wireless broadband communication technologies such as Global System for Mobile Communications (GSM), Code Division Multiple Access (CDMA), Universal Mobile Telecommunications System (UMTS), Worldwide Interoperability for Microwave Access (WiMAX), CDMA2000, Long Term Evolution (LTE), 3GPP, fifth-generation New Radio (5G NR) and/or other 5G networks, future generation networks, and/or the like. In some implementations, parallel ports, serial ports, USB connections, optical connections, or the like may also be used for connecting other computing devices or networks although they are usually considered as input/output interfaces for connecting input/output devices.

The input interface 510 may comprise one or more input modules for one or more users to input data via, for example, touch-sensitive screen, touch-sensitive whiteboard, touch-pad, keyboards, computer mouse, trackball, microphone, scanners, cameras, and/or the like. The input interface 510 may be a physically integrated part of the computing device 500 (for example, the touch-pad of a laptop computer or the touch-sensitive screen of a tablet), or may be a device physically separate from, but functionally coupled to, other components of the computing device 500 (for example, a computer mouse). The input interface 510, in some implementation, may be integrated with a display output to form a touch-sensitive screen or touch-sensitive whiteboard.

The output interface 512 may comprise one or more output modules for output data to a user. Examples of the output modules comprise displays (such as monitors, LCD displays, LED displays, projectors, and the like), speakers, printers, virtual reality (VR) headsets, augmented reality (AR) goggles, and/or the like. The output interface 512 may be a physically integrated part of the computing device 500 (for example, the display of a laptop computer or tablet), or may be a device physically separate from but functionally coupled to other components of the computing device 500 (for example, the monitor of a desktop computer).

The computing device 500 may also comprise other components 514 such as one or more positioning modules, temperature sensors, barometers, inertial measurement unit (IMU), and/or the like.

The system bus 518 may interconnect various components 502 to 514 enabling them to transmit and receive data and control signals to and from each other.

FIG. 19 shows a simplified software architecture of the computing device 500. On the software side, the computing device 500 may comprise one or more application programs 522, an operating system 524, a logical input/output (I/O) interface 526, and a logical memory 528. The one or more application programs 522, operating system 524, and logical I/O interface 526 may be implemented as computer-executable instructions or code in the form of software programs or firmware programs stored in the logical memory 528 which may be executed by the processing structure 502.

The one or more application programs 522 may be executed by or run by the processing structure 502 for performing various tasks.

The operating system 524 may manage various hardware components of the computing device 102 or 104 via the logical I/O interface 526, manages the logical memory 528, and may manage and supports the application programs 522. The operating system 524 may also be in communication with other computing devices (not shown) via the network 108 to allow application programs 522 to communicate with those running on other computing devices. As those skilled in the art will appreciate, the operating system 524 may be any suitable operating system such as MICROSOFT® WINDOWS® (MICROSOFT and WINDOWS are registered trademarks of the Microsoft Corp., Redmond, WA, USA), APPLE® OS X, APPLE® iOS (APPLE is a registered trademark of Apple Inc., Cupertino, CA, USA), Linux, ANDROID® (ANDROID is a registered trademark of Google LLC, Mountain View, CA, USA), or the like. The computing devices 500 may all have the same operating system, or may have different operating systems.

The logical I/O interface 526 may comprise one or more device drivers 530 for communicating with respective input and output interfaces 510 and 512 for receiving data therefrom and sending data thereto. Received data may be sent to the one or more application programs 522 for being processed by one or more application programs 522. Data generated by the application programs 522 may be sent to the logical I/O interface 526 for outputting to various output devices (via the output interface 512).

The logical memory 528 may be a logical mapping of the physical memory 506 for facilitating the application programs 522 to access. In this implementation, the logical memory 528 may comprise a storage memory area that may be mapped to a non-volatile physical memory such as hard disks, solid-state disks, flash drives, and the like, generally for long-term data storage therein. The logical memory 528 may also comprise a working memory area that is generally mapped to high-speed, and in some implementations volatile, physical memory such as RAM, generally for application programs 522 to temporarily store data during program execution. For example, an application program 522 may load data from the storage memory area into the working memory area, and may store data generated during its execution into the working memory area. The application program 522 may also store some data into the storage memory area as required or in response to a user's command.

As described above, the processing structure 502 may be of no use without meaningful firmware and/or software. Similarly, while the computing device 500 may have the potential to perform various tasks, it may not perform any tasks and may be of no use without meaningful firmware and/or software. Thus, the computing device 500 described herein and the modules, circuitries, and components thereof, as a combination of hardware and software, may generally produce tangible results tied to the physical world, wherein the tangible results such as those described herein may lead to improvements to the computer devices and systems themselves, the modules, circuitries, and components thereof, and/or the like.

In various implementations, the manufacturing apparatus described above may be any apparatus suitable for fabrication the electromagnetic structure 200. In some implementations, such a manufacturing apparatus may also comprise some or all components of above-described computing device, such as one or more processors, one or more controlling circuits or controllers, one or more non-transitory computer-readable memory or storage devices or media, input/output interface, and/or the like. The manufacturing apparatus may also comprise necessary and/or desired components that, under the control of one or more controllers, may transcript the designed shape to a substrate and fabricate the electromagnetic structure.

In some implementations, the EM software may integrate the methods disclosed herein, and therefore, no individual computation software is required.

In some implementations, the EM software may be integrated into the manufacturing apparatus, and one may only need the computation software for performing the methods disclosed herein in a computing device and then using the manufacturing apparatus to design and fabricate the electromagnetic structure with optimized shape.

In some implementations, the computation software may be integrated into the manufacturing apparatus.

In some implementations, the computation software and the EM software may be integrated into the manufacturing apparatus. Therefore, no individual computing devices are required.

Herein, various implementations of methods are described. In some implementations, the methods disclosed herein may be implemented as one or more circuits of a module, a device, an apparatus, a system, and/or the like. In some implementations, the methods disclosed herein may be implemented as computer-executable instructions stored in one or more non-transitory computer-readable storage devices such that, the instructions, when executed, may cause one or more circuits to perform the methods disclosed herein.

According to various implementations of this disclosure, the methods disclosed herein can provide design optimization of a planar EM structure with an increased number of variable vertices and an increased degree of freedom. Variable vertices can be optimized inside given geometric shapes and both 1D variation and 2D variation are possible. Optimization boundary for each variable can be set with different geometric shapes, allowing successful optimization of each vertex based on desired performance measures of the electromagnetic structure.

In some implementations, multiple slots can be accommodated by managing the number of total variables in desired manner. Microstrip antennas and filters can be developed to achieve desired impedance bandwidth, bandpass and/or bandstop performance and other radiation characteristics. Performance parameters (such as AR) can be optimized by the described methods, making higher order modes tunable which contributes to the wideband response.

Compared to some or most methods, the methods disclosed in various implementations can provide better performances in that:
Classical shapes of patch cannot manipulate fundamental and higher order modes for various applications such as multiband and wideband applications. In contrast, modes of different order can be turned by varying the variable vertices based on desired applications.
Demonstrated examples show that the antenna designed according to various implementations of this disclosure can provide circular polarization (axial ratio<=3 dB) characteristics. Therefore, different performance parameters can be optimized according to the desired applications.

Thus, the various implementations disclosed herein provide a method of electromagnetic structure design and/or fabrication suitable for manipulating fundamental and higher order modes for a variety of applications such as multiband and wideband applications. The examples demonstrated also show that the electromagnetic structure designed according to the implementations can be optimized for different performance parameters such as circular polarization characteristics (e.g., with an axial ratio of equal or less than 3 decibels (dB)).

Herein, use of language such as “at least one of X, Y, and Z,” “at least one of X, Y, or Z,” “at least one or more of X, Y, and Z,” “at least one or more of X, Y, and/or Z,” or “at least one of X, Y, and/or Z,” is intended to be inclusive of both a single item (e.g., just X, or just Y, or just Z) and multiple items (e.g., {X and Y}, {X and Z}, {Y and Z}, or {X, Y, and Z}). The phrase “at least one of” and similar phrases are not intended to convey a requirement that each possible item must be present, although each possible item may be present.

In some implementations, the methods disclosed herein may be implemented as computer-executable instructions stored in one or more non-transitory computer-readable storage devices (in the form of software, firmware, or a combination thereof) such that, the instructions, when executed, may cause one or more physical components such as one or more circuits to perform the methods disclosed herein.

For example, in some implementations, one or more apparatuses comprising one or more processors functionally connected to one or more non-transitory computer-readable storage devices or media or medium may be used to perform the methods disclosed herein, wherein the one or more non-transitory computer-readable storage devices or media or medium store the computer-executable instructions of the methods disclosed herein, and the one or more processors may read the computer-executable instructions from the one or more non-transitory computer-readable storage devices or media or medium, and executes the instructions to perform the methods disclosed herein.

In some implementations, an apparatus may not have any processors or computer-readable storage devices or media or medium. Rather, the apparatus may comprise any other suitable physical or virtual (explained below) components for implementing the methods disclosed herein.

In some implementations, the computer-executable instructions that implement the methods disclosed herein may be one or more computer programs, one or more program products, or a combination thereof.

In some implementations, the methods disclosed herein may be implemented as one or more circuits, one or more components, one or more units, one or more modules, one or more integrated-circuit (IC) chips, one or more chipsets, one or more devices, one or more apparatuses, one or more systems, and/or the like.

The one or more circuits, one or more components, one or more units, one or more modules, one or more IC chips, one or more chipsets, one or more devices, one or more apparatuses, or one or more systems may be physical, virtual, or a combination thereof. Herein, the term “virtual” (such as a “virtual apparatus”) refers to a circuit, component, unit, module, chipset, device, apparatus, system, or the like that is simulated or emulated or otherwise formed using suitable software or firmware such that it appears as if it is “real” or physical).

The present disclosure encompasses various implementations, including not only method implementations, but also other implementations such as apparatus implementations and implementations related to non-transitory computer readable storage media. Implementations may incorporate, individually or in combinations, the features disclosed herein.

Those skilled in the art will appreciate that such various implementations and/or features thereof may be customized and/or combined as needed or desired. Moreover, although implementations have been described above with reference to the accompanying drawings, those of skill in the art will appreciate that variations and modifications may be made without departing from the scope thereof as defined by the appended claims.

Although this disclosure refers to illustrative implementations, this is not intended to be construed in a limiting sense. Various modifications and combinations of the illustrative implementations, as well as other implementations of the disclosure, will be apparent to persons skilled in the art upon reference to the description.

Features disclosed herein in the context of any particular implementations may also or instead be implemented in other implementations. Method implementations, for example, may also or instead be implemented in apparatus, system, and/or computer program product implementations. In addition, although implementations are described primarily in the context of methods and apparatus, other implementations are also contemplated, as instructions stored on one or more non-transitory computer-readable media, for example. Such media may store programming or instructions to perform any of various methods consistent with the present disclosure.

Those skilled in the art will appreciate that the above-described implementations and/or features thereof may be customized, separated, and/or combined as needed or desired. Moreover, although implementations have been described above with reference to the accompanying drawings, those of skill in the art will appreciate that variations and modifications may be made without departing from the scope thereof as defined by the appended claims.

What is claimed is:

1. A method comprising:
determining a shape of a planar electromagnetic structure for optimizing one or more performance measures of the planar electromagnetic structure, the shape of the planar electromagnetic structure being defined by a plurality of vertices; wherein
said determining the shape of the planar electromagnetic structure comprises determining locations of the plurality of vertices, a location of each vertex of the plurality of vertices being selected from a plurality of candidates variable within a corresponding geometric shape from a plurality of geometric shapes, and
at least one of the plurality of geometric shapes is a two-dimensional geometric shape and the location of at least one vertex of the plurality of vertices is selected from a plurality of candidates variable with respect to two dimensions independently within the two-dimensional geometric shape.

2. The method of claim 1, wherein the plurality of geometric shapes comprises one or more of a straight line, a rectangular shape, or a triangular shape.

3. The method of claim 1, wherein each of the plurality of geometric shapes comprises boundaries determined based on a target frequency range of the planar electromagnetic structure.

4. The method of claim 3, wherein each of the plurality of candidates represents coordinates within the boundaries of the corresponding geometric shape.

5. The method of claim 1, wherein each vertex of the plurality of vertices is represented as a coordinate pair in a Cartesian coordinate system.

6. The method of claim 1, wherein said determining the shape of the electromagnetic structure further comprises:
determining a location of a feed point of the planar electromagnetic structure.

7. The method of claim 1, further comprising:
fabricating the planar electromagnetic structure having the shape defined by the plurality of vertices at the determined locations thereof.

8. The method of claim 1, wherein the planar electromagnetic structure is at least a portion of a transmitter or a receiver.

9. The method of claim 1, wherein the determining the locations of the plurality of vertices of the shape of the planar electromagnetic structure is performed using an artificial intelligence (AI) model.

10. The method of claim 9, wherein the AI model comprises a convolutional neural network (CNN) model.

11. The method of claim 9, wherein the AI model receives a value of a frequency as a parameter for optimizing the one or more performance measures of the electromagnetic structure.

12. The method of claim 1, wherein the one or more performance measures of the planar electromagnetic structure comprises one or more scattering parameters of the planar electromagnetic structure.

13. The method of claim 1, wherein the one or more performance measures of the planar electromagnetic structure comprises a return loss parameter S₁₁ of the planar electromagnetic structure.

14. The method of claim 9, wherein the determining the locations of the plurality of vertices of the shape of the planar electromagnetic structure is performed using the AI and a genetic algorithm.

15. The method of claim 1, wherein said determining the shape of the planar electromagnetic structure further comprises:
simulating the planar electromagnetic structure having the shape defined by the plurality of vertices; and
comparing results of said simulation with the one or more performance measures for optimization verification.

16. The method of claim 9, further comprising:
selecting the locations of the plurality of vertices; and
simulating the planar electromagnetic structure having the shape defined by the plurality of vertices at the locations selected by the computational software; and
collecting the selected locations and results of said simulation as data for training the AI model.

17. The method of claim 16, wherein selecting the locations of the plurality of vertices is performed by a computational software; and
wherein said simulating the planar electromagnetic structure is performed by a full-wave electromagnetic simulation software.

18. The method of claim 1 further comprising:
repeating said determining the shape of the planar electromagnetic structure for a plurality of times to obtain a plurality of shapes of the electromagnetic structure; and
selecting one of the plurality of shapes of the planar electromagnetic structure based on one or more requirements of a use case.

19. One or more apparatuses comprising:
one or more processors; and
a memory storing instructions which, when executed by the one or more processors, cause the apparatus to:
determine a shape of a planar electromagnetic structure for optimizing one or more performance measures of the planar electromagnetic structure, the shape of the planar electromagnetic structure being defined by a plurality of vertices; wherein
causing the one or more processors to determine the shape of the planar electromagnetic structure comprises causing the one or more processors to determine locations of the plurality of vertices, a location of each vertex of the plurality of vertices being selected from a plurality of candidates variable within a corresponding geometric shape from a plurality of geometric shapes, and
at least one of the plurality of geometric shapes is a two-dimensional geometric shape and the location of at least one vertex of the plurality of vertices is selected from a plurality of candidates variable with respect to two dimensions independently within the two-dimensional geometric shape.

20. A computer-readable storage medium having instructions stored thereon which, when executed by one or more processors, cause the one or more processors to:
determine a shape of a planar electromagnetic structure for optimizing one or more performance measures of the planar electromagnetic structure, the shape of the planar electromagnetic structure being defined by a plurality of vertices; wherein
causing the one or more processors to determine the shape of the planar electromagnetic structure comprises causing the one or more processors to determine locations of the plurality of vertices, a location of each vertex of the plurality of vertices being selected from a plurality of candidates variable within a corresponding geometric shape from a plurality of geometric shapes, and
at least one of the plurality of geometric shapes is a two-dimensional geometric shape and the location of at least one vertex of the plurality of vertices is selected from a plurality of candidates variable with respect to two dimensions independently within the two-dimensional geometric shape.
